(19) United States
(12) Patent Application Publication
(10) Pub. No.: US 2026/0157061 A1
(43) Pub. Date: Jun. 4, 2026

(54) ELECTRONIC DEVICE

(71) Applicant: Samsung Display Co., Ltd., Yongin-si (KR)

(72) Inventors: JONG-RYUK PARK, Yongin-si (KR); TAEGON KIM, Yongin-si (KR)

(21) Appl. No.: 19/349,757

(22) Filed: Oct. 3, 2025

(30) Foreign Application Priority Data
Dec. 3, 2024 (KR) 10-2024-0177292

(51) Int. Cl. H10K 59/131; G06F 3/044; H10K 59/40

(52) U.S. Cl. CPC H10K 59/131; G06F 3/0445; G06F 3/0446; H10K 59/40; G06F 2203/04111

(57) ABSTRACT

An electronic device may include signal lines and pads. Each of the pads may include a first lower conductive pattern on the base layer, a first insulating pattern through which a contact hole is defined to expose a portion of the first lower conductive pattern, the first insulating pattern covering the first lower conductive pattern, a second lower conductive pattern including a first portion covering the first lower conductive pattern exposed through the contact hole and a second portion extending from a side surface of the first insulating pattern, which defines the contact hole, and the first portion to cover an upper surface of the first insulating pattern, a second-first insulating pattern on the first portion, a first upper conductive pattern on the second-first insulating pattern, and a second upper conductive pattern on the first upper conductive pattern and being in contact with the first upper conductive pattern.

### CROSS-REFERENCE TO RELATED APPLICATION

The present application claims priority to and the benefit of Korean Patent Application No. 10-2024-0177292, filed on Dec. 3, 2024, in the Korean Intellectual Property Office, the entire disclosure of which is incorporated herein by reference.

### BACKGROUND

### 1. Field

One or more embodiments of the present disclosure relate to an electronic device. For example, one or more embodiments of the present disclosure relate to an electronic device including a pad.

2. Description of Related Art

Various electronic devices applied to multimedia devices, such as televisions, mobile phones, tablet computers, navigation devices, and/or game devices, are being developed. These electronic devices include multiple electronic components. The electronic components include a display panel, a driving chip, a circuit board, and/or the like. The electronic components are electrically connected in one or more suitable ways.

### SUMMARY

One or more aspects of embodiments of the present disclosure are directed toward an electronic device with improved or enhanced electrical bonding reliability and reduced defects in pads of a pad part of the electronic device.

Additional aspects of embodiments will be set forth in part in the description which follows and, in part, will be apparent from the description or may be learned by practice of the presented embodiments of the disclosure.

One or more embodiments of the present disclosure provide an electronic device including a base layer, pixels on the base layer, signal lines electrically connected to the pixels, and pads connected to the signal lines.

Each of the pads includes a first lower conductive (e.g., electrically conductive) pattern arranged on the base layer, a first insulating (e.g., electrically insulating) pattern through which a contact hole is defined to expose a portion of the first lower conductive pattern, the first insulating pattern covering the first lower conductive pattern, a second lower conductive (e.g., electrically conductive) pattern including a first portion covering the first lower conductive pattern exposed through the contact hole and a second portion extending from a side surface of the first insulating pattern, which defines the contact hole, and the first portion to cover an upper surface of the first insulating pattern, a second-first insulating (e.g., electrically insulating) pattern arranged on the first portion, a first upper conductive (e.g., electrically conductive) pattern arranged on the second-first insulating pattern, and a second upper conductive (e.g., electrically conductive) pattern arranged on the first upper conductive pattern and being in contact with the first upper conductive pattern.

The first upper conductive pattern may not be in contact with the first portion and may be in contact with the second portion.

The contact hole may overlap the first lower conductive pattern if (e.g., when) viewed on a plane (e.g., in plan view).

The second upper conductive pattern may have an area greater than an area of the first upper conductive pattern if (e.g., when) viewed on a plane (e.g., in plan view).

Each of edges of the second upper conductive pattern may be spaced and/or apart (e.g., spaced apart or separated) from the first insulating pattern, and the second-first insulating pattern may be arranged between the each of the edges of the second upper conductive pattern and the first insulating pattern.

The first upper conductive pattern may be spaced and/or apart (e.g., spaced apart or separated) from the first lower conductive pattern.

The second-first insulating pattern may be arranged inside the contact hole.

A distance between an uppermost portion of the second lower conductive pattern and the first lower conductive pattern may be greater than a distance between an upper surface of the second-first insulating pattern and the first lower conductive pattern.

The electronic device may further include a second-second insulating (e.g., electrically insulating) pattern arranged on the first insulating pattern and spaced and/or apart (e.g., spaced apart or separated) from the second-first insulating pattern.

The second-second insulating pattern may cover the second lower conductive pattern.

Each of the first upper conductive pattern and the second upper conductive pattern may include a first layer including titanium, a second layer including aluminum, and a third layer including titanium, wherein the first layer, the second layer, and the third layer are sequentially stacked in a direction away from the first lower conductive pattern.

The electronic device may further include a circuit board to apply an electrical signal to the pixels and including a bump connecting the second upper conductive pattern and the first upper conductive pattern.

The electronic device may further include an input sensing layer arranged on the base layer. The input sensing layer may include a first sensing insulating (e.g., electrically insulating) layer, a second sensing insulating (e.g., electrically insulating) layer, and a third sensing insulating (e.g., electrically insulating) layer that are sequentially stacked in a direction away from the first lower conductive pattern, a first sensing conductive (e.g., electrically conductive) layer arranged between the first sensing insulating layer and the second sensing insulating layer, and a second sensing conductive (e.g., electrically conductive) layer arranged between the second sensing insulating layer and the third sensing insulating layer.

Each of the pads may further include a third upper conductive (e.g., electrically conductive) pattern including substantially the same material as one selected from among the first sensing conductive layer and the second sensing conductive layer.

One or more embodiments of the present disclosure provide an electronic device including a base layer, pixels arranged on the base layer, signal lines electrically connected to the pixels, and pads connected to the signal lines. Each of the pads includes a first lower conductive (e.g., electrically conductive) pattern arranged on the base layer, a first insulating (e.g., electrically insulating) pattern through which contact holes are defined to expose the first lower conductive pattern, the contact holes being spaced and/or apart (e.g., spaced apart or separated) from each other and the first insulating pattern covering the first lower conductive pattern, a second lower conductive (e.g., electrically conductive) pattern including first portions covering the first lower conductive pattern exposed through the contact holes and second portions extending from a side surface of the first insulating pattern, which defines the contact hole, and the first portion to cover an upper surface of the first insulating pattern, second-first insulating (e.g., electrically insulating) patterns arranged on the first portions, a first upper conductive (e.g., electrically conductive) pattern arranged on the second-first insulating patterns and the second lower conductive pattern, and a second upper conductive (e.g., electrically conductive) pattern arranged on the first upper conductive pattern and being in contact with the first upper conductive pattern.

The second-first insulating patterns may be arranged in the contact holes adjacent to each other and have a shape extending along one direction if (e.g., when) viewed on a plane (e.g., in plan view).

The first upper conductive pattern may not be in contact with the first portions and may be in contact with the second portions.

The electronic device may further include a second-second insulating (e.g., electrically insulating) pattern arranged on the first insulating pattern and spaced and/or apart (e.g., spaced apart or separated) from the second-first insulating patterns, and the second-second insulating pattern may cover the first insulating pattern.

The electronic device may further include an input sensing layer arranged on the base layer. The input sensing layer may include a first sensing insulating (e.g., electrically insulating) layer, a second sensing insulating (e.g., electrically insulating) layer, and a third sensing insulating (e.g., electrically insulating) layer that are sequentially stacked in a direction away from the first lower conductive pattern, a first sensing conductive (e.g., electrically conductive) pattern arranged between the first sensing insulating layer and the second sensing insulating layer, and a second sensing conductive (e.g., electrically conductive) pattern arranged between the second sensing insulating layer and the third sensing insulating layer, and each of the pads may further include a third upper conductive (e.g., electrically conductive) pattern including substantially the same material as one selected from among the first sensing conductive pattern and the second sensing conductive pattern.

The second-first insulating pattern may include a second-first insulating (e.g., electrically insulating) portion arranged on the first lower conductive pattern and arranged inside the contact holes and a second-second insulating (e.g., electrically insulating) portion arranged outside the contact holes, and the third upper conductive pattern may include a protrusion protruded in a direction away from the base layer and overlapping the second-second insulating portion.

In one or more embodiments, the electronic device with improved or enhanced electrical reliability may be provided. The enhancements in electrical reliability ensure that the device maintains stable and consistent performance over time, reducing the likelihood of electrical failures and improving the overall user experience.

In one or more embodiments, peeling or detachment of a portion of the conductive pattern, caused by curvature occurring in the conductive pattern included in the pad, may be prevented (or a degree or occurrence of peeling or detachment of a portion of the conductive pattern, caused by curvature occurring in the conductive pattern included in the pad, may be reduced). This reduction in peeling or detachment helps maintain the integrity of the electrical connections within the device, thereby enhancing its durability and operational lifespan. By addressing these issues, the electronic device may achieve higher reliability and performance standards, making it more robust and dependable for various applications.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a perspective view of an electronic device according to one or more embodiments of the present disclosure;

FIGS. 2A and 2B are exploded perspective views of an electronic device according to one or more embodiments of the present disclosure;

FIG. 3 is a block diagram of an electronic device according to one or more embodiments of the present disclosure;

FIG. 4 is a cross-sectional view of a display module according to one or more embodiments of the present disclosure;

FIG. 5A is a plan view of a display panel according to one or more embodiments of the present disclosure;

FIG. 5B is a cross-sectional view of a display panel according to one or more embodiments of the present disclosure;

FIG. 6A is a cross-sectional view of an input sensing layer according to one or more embodiments of the present disclosure;

FIG. 6B is a plan view of an input sensing layer according to one or more embodiments of the present disclosure;

FIG. 6C is a cross-sectional view of an input sensing layer taken along the line X-X′ of FIG. 6B;

FIG. 7 is an enlarged exploded perspective view of a pad area of an electronic device according to one or more embodiments of the present disclosure;

FIG. 8A is an enlarged cross-sectional view of a pad area of an electronic device according to a comparative example;

FIG. 8B is an enlarged view of an area AA′ of FIG. 8A;

FIG. 9A is an enlarged cross-sectional view of a pad area of an electronic device according to one or more embodiments of the present disclosure;

FIG. 9B is an enlarged view of an area BB′ of FIG. 9A;

FIG. 9C is an enlarged plan view of a pad area according to one or more embodiments of the present disclosure;

FIG. 9D is a cross-sectional view of a bonding structure of an electronic device according to one or more embodiments of the present disclosure;

FIG. 10A is an enlarged cross-sectional view of a pad area of an electronic device according to one or more embodiments of the present disclosure;

FIG. 10B is an enlarged plan view of a pad area of an electronic device according to one or more embodiments of the present disclosure;

FIG. 10C is a cross-sectional view of a bonding structure of an electronic device according to one or more embodiments of the present disclosure;

FIG. 11 is an enlarged cross-sectional view of a pad area of an electronic device according to one or more embodiments of the present disclosure; and

FIG. 12 is an enlarged cross-sectional view of a pad area of an electronic device according to one or more embodiments of the present disclosure.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items. For example, “A and/or B” indicates cases where it is A, or B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that if (e.g., when) an element (or an area, a layer, or a portion) is referred to as being “on”, “connected to”, or “coupled to” another element, it may be directly on, directly connected to, or directly coupled to the other element or intervening elements may be present therebetween. In contrast, if (e.g., when) an element is referred to as being “directly on”, “directly conncected to”, or “directly coupled to” another element, there are no intervening elements present therebetween.

In the drawings, the thickness, ratio, and dimension of components may be exaggerated for effective description of the technical content.

It will be understood that, although the terms “first”, “second”, and/or the like may be used herein to describe one or more suitable elements, these elements should not be limited by these terms. These terms are only used to distinguish one element from another element. Thus, a first element discussed herein may be termed a second element without departing from the scope of the present disclosure.

As used herein, the singular forms, “a”, “an”, and “the” are intended to include the plural forms as well, unless the context clearly indicates otherwise.

Spatially relative terms, such as “beneath”, “below”, “lower”, “above”, “upper” and/or the like, may be used herein for ease of description to describe one element or feature's relationship to another elements or features as illustrated in the drawings.

It will be further understood that the terms “have”, “having”, “include” and/or “including”, if (e.g., when) used in the present disclosure, specify the presence of stated features, integers, steps, operations, elements, and/or components, but do not preclude the presence or addition of one or more other features, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Unless otherwise defined, all terms used herein have substantially the same meaning as generally understood by one of ordinary skill in the art to which the present disclosure belongs. It will be further understood that terms, such as those defined in generally-used or generally available dictionaries, should be interpreted as having a meaning that is substantially consistent with their meaning in the context of the relevant art and will not be interpreted in an idealized or overly formal sense unless expressly so defined herein.

Hereinafter, one or more embodiments of the present disclosure will be described in more detail with reference to the accompanying drawings.

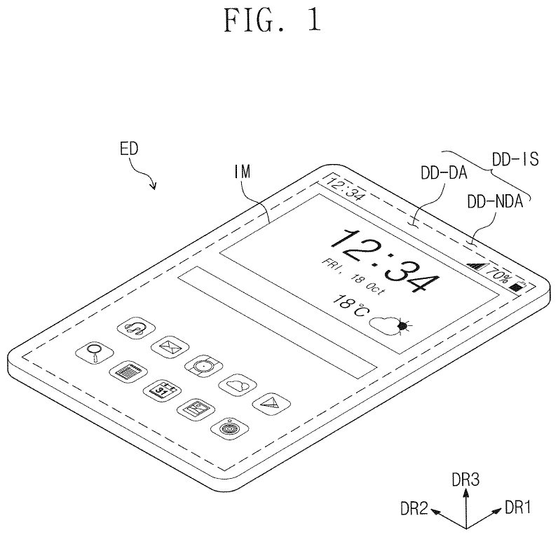

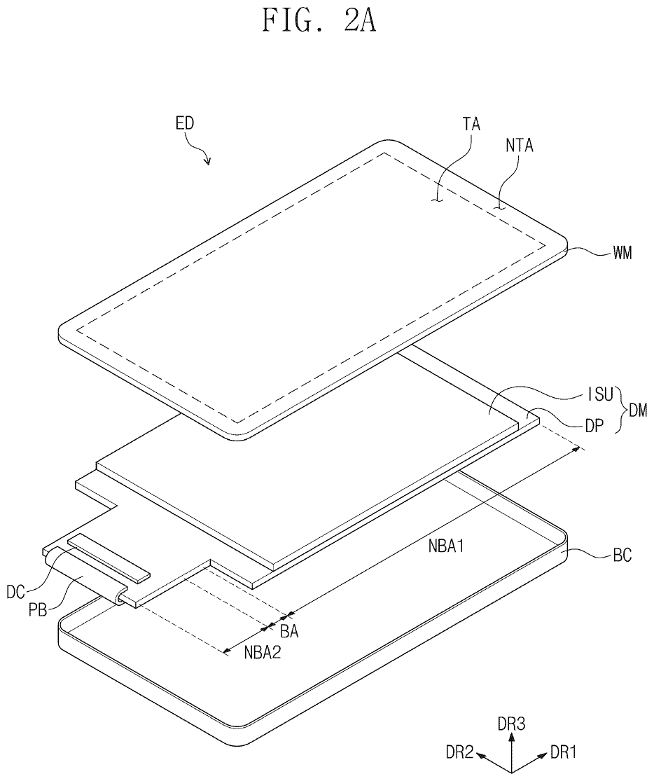

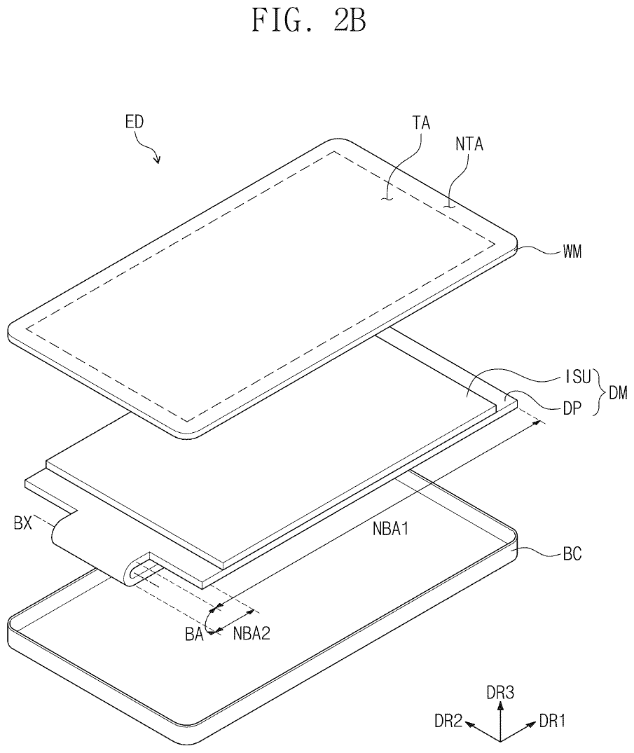

FIG. 1 is a perspective view of an electronic device according to one or more embodiments of the present disclosure. FIGS. 2A and 2B are exploded perspective views of an electronic device according to one or more embodiments of the present disclosure.

The electronic device ED according to one or more embodiments of the present disclosure may be applied to large-sized electronic devices, such as television sets and/or monitors, and/or small-sized electronic devices and/or medium-sized electronic devices, such as tablet computers, car navigation units, game units, and/or smart watches. FIG. 1 illustrates a smartphone terminal as the electronic device ED as an example, however, embodiments of the present disclosure are not limited thereto.

The electronic device ED may have a rectangular shape (e.g., a substantially rectangular shape) defined by long sides extending in a first direction DR1 and short sides extending in a second direction DR2 crossing (e.g., intersecting) the first direction DR1. However, the shape of the electronic device ED should not be limited to the rectangular shape, and the electronic device ED may have one or more suitable shapes, such as a circular shape (e.g., a substantially circular shape) and a polygonal shape (e.g., a substantially polygonal shape).

Hereinafter, a direction substantially normal (e.g., perpendicular) to a plane defined by the first direction DR1 and the second direction DR2 may be referred to as a third direction DR3. In the present disclosure, the expression “if (e.g., when) viewed on a plane (e.g., in plan view)” may refer to a state of being viewed in the third direction DR3.

The electronic device ED may be rigid or flexible. The term “flexible” used herein refers to the property of being able to be bent from a structure that is completely bent to a structure that is bent at the scale of a few nanometers. For example, the flexible electronic device ED may be a curved electronic device, a rollable electronic device, or a foldable electronic device.

The electronic device ED may be to display an image IM through a display surface DD-IS. Icon images are illustrated as an example of the image IM. The display surface DD-IS may be substantially parallel to the plane defined by the first direction DR1 and the second direction DR2.

The display surface DD-IS may include a display area DD-DA through which the image IM is displayed and a non-display area DD-NDA defined adjacent to the display area DD-DA. The image IM may not be displayed through the non-display area DD-NDA. According to one or more embodiments, the non-display area DD-NDA may be defined adjacent to one side of the display area DD-DA or may not be provided.

Referring to FIGS. 2A and 2B, the electronic device ED may include a window WM, a display module DM, and an accommodation member BC. FIG. 2B illustrates a bent state of a bending area BA of the display module DM as illustrated in FIG. 2A.

The window WM may be arranged on the display module DM. The window WM may be to transmit the image IM provided from the display module DM to the outside of the display module DM. The window WM may include a transmission area TA and a non-transmission area NTA. The transmission area TA may overlap the display area DD-DA as illustrated in FIG. 1 and may have a shape corresponding to that of the display area DD-DA.

In one or more embodiments, the window WM may include a base layer and functional layers arranged on the base layer. The functional layers may include a protective layer, an anti-fingerprint layer, and/or the like. The base layer of the window WM may include a glass, sapphire, and/or plastic material. The base layer of the window WM may include an optically transparent (e.g., substantially transparent) insulating (e.g., electrically insulating) material. For example, the base layer of the window WM may include a glass and/or a plastic film or may include a glass substrate and a plastic film coupled to the glass substrate by an adhesive.

The non-transmission area NTA may overlap the non-display area DD-NDA as illustrated in FIG. 1 and may have a shape corresponding to that of the non-display area DD-NDA. The non-transmission area NTA may have a relatively low light transmittance compared to that of the transmission area TA. The non-transmission area NTA may be defined in a portion of the base layer of the window WM by a bezel pattern, and an area in which the bezel pattern is not arranged may be defined as the transmission area TA. However, embodiments of the present disclosure are not limited thereto, and the non-transmission area NTA may not be provided.

In one or more embodiments, an anti-reflective layer may be arranged between the window WM and the display module DM. The anti-reflective layer may reduce a reflectance (e.g., a degree or occurrence of a reflectance) of the electronic device ED with respect to the external light provided from the outside of the electronic device ED. The anti-reflective layer may include color filters. The color filters may be arranged in a selected (e.g., set or predetermined) arrangement. As an example, the color filters may be arranged by taking into account light emission colors of pixels included in the display panel DP as described in more detail herein. In one or more embodiments, the anti-reflective layer may further include a black matrix arranged adjacent to the color filters.

The display module DM may include the display panel DP and an input sensing layer ISU.

The display panel DP may be one selected from among a liquid crystal display panel, an electrophoretic display panel, a microelectromechanical system (MEMS) display panel, an electrowetting display panel, an organic light emitting display panel, an inorganic light emitting display panel, and a quantum dot light emitting display panel. Hereinafter, the organic light emitting display panel will be described in more detail as the display panel DP, however, the type (kind) of the display panel DP should not be limited.

The input sensing layer ISU may include one selected from among a capacitive sensor, an optical sensor, an ultrasonic sensor, and an electromagnetic induction sensor. The input sensing layer ISU may be formed or arranged on the display panel DP through a substantially continuous process or may be attached to an upper portion of the display panel DP utilizing an adhesive layer after being separately manufactured.

The electronic device ED may further include a driving chip DC mounted on the display panel DP.

The electronic device ED may further include a circuit board PB mounted on the display panel DP.

In one or more embodiments of the present disclosure, the circuit board PB may be a flexible circuit board, however, embodiments of the present disclosure are not limited thereto. As an example, the circuit board PB may be rigid. The circuit board PB may electrically connect the display panel DP and a main circuit board.

The driving chip DC may include driving elements, e.g., a data driving circuit, to drive the pixels of the display panel DP. FIG. 2A illustrates a structure in which the driving chip DC may be mounted on the display panel DP, however, embodiments of the present disclosure are not limited thereto. As an example, the driving chip DC may be mounted on the circuit board PB.

In one or more embodiments, the driving chip DC and the circuit board PB, which are directly mounted on the display panel DP, may be collectively referred to as “electronic components”. A bonding structure between the display panel DP and the circuit board PB to be described in more detail hereinafter may be equally applied to the driving chip DC and other electronic components in addition to the circuit board PB.

The display panel DP may include a bending area BA, a first non-bending area NBA1, and a second non-bending area NBA2 spaced and/or apart (e.g., spaced apart or separated) from the first non-bending area NBA1 in the first direction DR1, and the bending area BA may be arranged between the first non-bending area NBA1 and the second non-bending area NBA2.

The bending area BA may be an area in which the display panel DP is bent about an imaginary bending axis BX extending in the second direction DR2. The first non-bending area NBA1 may overlap the transmission area TA, and the circuit board PB may be connected to the second non-bending area NBA2.

Referring to FIG. 2B, if (e.g., when) the bending area BA is bent about the bending axis BX, the circuit board PB and the driving chip DC may be bent in a direction toward a rear surface of the display panel DP and thus may be arranged under the rear surface of the display panel DP. As a portion of the display panel DP is bent, the circuit board PB electrically bonded to the display panel DP may be arranged on the rear surface of the display panel DP.

The accommodation member BC may provide a space to accommodate the display module DM. The accommodation member BC may be to protect the display module DM from external impacts. In one or more embodiments, the accommodation member BC may prevent a foreign substance from entering the electronic device ED from the outside (or reduce a degree to or occurrence of which a foreign substance enters the electronic device ED from the outside). The accommodation member BC may be coupled with the window WM.

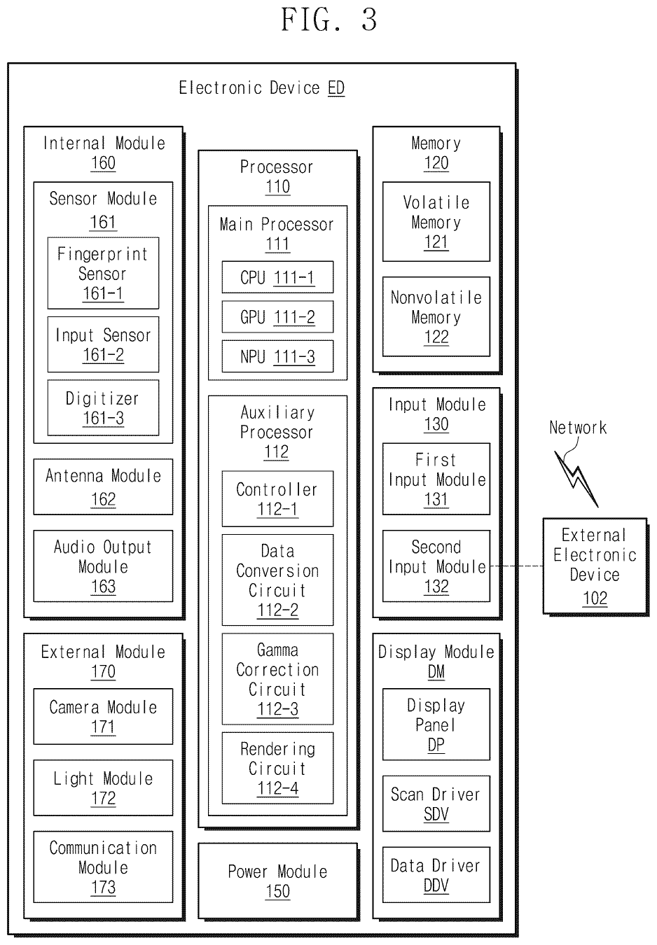

FIG. 3 is a block diagram of the electronic device according to one or more embodiments of the present disclosure.

Referring to FIG. 3, the electronic device ED may communicate with an external electronic device 102 through a network (for example, a short-range wireless communication network or a long-range wireless communication network). According to one or more embodiments, the electronic device ED may include a processor 110, a memory 120, an input module 130, a display module DM, a power module 150, an internal module 160, and an external module 170. According to one or more embodiments, in the electronic device ED, at least one selected from among the components as described in one or more embodiments may not be provided or one or more other components may be added. According to one or more embodiments, one or more of the components (for example, a sensor module 161, an antenna module 162, and/or an audio output module 163) as described in one or more embodiments may be integrated into another component (for example, the display module DM).

The processor 110 may be to execute software to control at least one other component (for example, a hardware component and/or a software component) of the electronic device ED connected to the processor 110 and may be to perform one or more suitable data processing or computational operations. According to one or more embodiments, as at least a part of the data processing or computational operations, the processor 110 may be to store commands or data received from other components (for example, the input module 130, the sensor module 161, and/or a communication module 173) in a volatile memory 121, may be to process the commands or the data stored in the volatile memory 121, and may be to store result data in a nonvolatile memory 122.

The processor 110 may include a main processor 111 and an auxiliary processor 112. The main processor 111 may include one or both (e.g., simultaneously) selected from among a central processing unit (CPU) 111-1 and an application processor (AP). The main processor 111 may further include any one or more selected from among a graphics processing unit (GPU) 111-2, a communication processor (CP), and an image signal processor (ISP).

The main processor 111 may further include a neural processing unit (NPU) 111-3. The NPU may be a processor specialized in processing an artificial intelligence model, and the artificial intelligence model may be generated through machine learning. The artificial intelligence model may include a plurality of artificial neural network layers. The artificial neural network may be one selected from among a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, and/or a (e.g., any suitable) combination of two or more of the above, but is not limited to the example as described in one or more embodiments. In one or more embodiments, additionally or alternatively, the artificial intelligence model may include a software structure in addition to a hardware structure. At least two selected from among the processing units and processors as described in one or more embodiments may be implemented as a single integrated component (for example, a single chip) or as separate components (for example, a plurality of chips).

The auxiliary processor 112 may include a controller 112-1. The controller 112-1 may include an interface conversion circuit and a timing control circuit. The controller 112-1 may be to receive an image signal from the main processor 111, convert a data format of the image signal to correspond to an interface specification with the display module DM, and output image data. The controller 112-1 may be to output one or more suitable control signals desired or required to drive the display module DM.

The auxiliary processor 112 may further include a data conversion circuit 112-2, a gamma correction circuit 112-3, a rendering circuit 112-4, and/or the like. The data conversion circuit 112-2 may be to receive the image data from the controller 112-1, compensate for the image data to display an image with a desired or suitable luminance based on characteristics of the electronic device ED, user settings, and/or the like, or convert the image data to reduce power consumption or to compensate for image retention.

The gamma correction circuit 112-3 may be to convert the image data, a gamma reference voltage, and/or the like so that the image displayed on the electronic device ED has a desired or suitable gamma characteristic. The rendering circuit 112-4 may be to receive the image data from the controller 112-1 and render the image data taking into account a pixel arrangement and/or the like of a display panel DP applied to the electronic device ED.

At least one selected from among the data conversion circuit 112-2, the gamma correction circuit 112-3, and the rendering circuit 112-4 may be integrated into another component (for example, the main processor 111 or the controller 112-1). At least one selected from among the data conversion circuit 112-2, the gamma correction circuit 112-3, and the rendering circuit 112-4 may be integrated into a data driver DDV, which is described in more detail herein. The data driver DDV may be a portion of a circuit included in a driving chip DC as illustrated in FIG. 2.

The memory 120 may be to store one or more suitable data used by at least one component (for example, the processor 110 or the sensor module 161) of the electronic device ED and input or output data related to corresponding commands. The memory 120 may include at least one selected from among the volatile memory 121 and the nonvolatile memory 122.

The input module 130 may be to receive commands or data to be used by a component (for example, the processor 110, the sensor module 161, or the audio output module 163) of the electronic device ED from an external source (for example, the user or the external electronic device 102) of the electronic device ED.

The input module 130 may include a first input module 131 receiving commands or data from the user and a second input module 132 receiving commands or data from the external electronic device 102. The first input module 131 may include a microphone, a mouse, a keyboard, a key (for example, a button), and/or a pen (for example, a passive pen and/or an active pen).

The second input module 132 may be to support a designated protocol that enables connection to the external electronic device 102 via a wired connection and/or a wireless connection. According to one or more embodiments, the second input module 132 may include a high definition multimedia interface (HDMI), a universal serial bus (USB) interface, an SD card interface, or an audio interface. The second input module 132 may include a connector capable of physically connecting to the external electronic device 102, for example, an HDMI connector, a USB connector, an SD card connector, or an audio connector (for example, a headphone connector).

The display module DM may be to provide visual information to the user. The display module DM may include the display panel DP, a scan driver SDV, and the data driver DDV. The display module DM may further include a window, a chassis, and a bracket to protect the display panel DP.

The display panel DP may include a liquid crystal display panel, an organic light emitting display panel, or an inorganic light emitting display panel, and a type (kind) of the display panel DP should not be limited. The display panel DP may be a rigid type (kind) or a flexible type (kind) that may be rolled or folded. The display module DM may further include a supporter, a bracket, a heat dissipation member, and/or the like that supports the display panel DP.

The scan driver SDV may be mounted on the display panel DP as a driving chip. In one or more embodiments, the scan driver SDV may be integrated in the display panel DP. For example, the scan driver SDV may include an amorphous (e.g., non-crystalline) silicon TFT gate driver circuit (ASG), a low temperature polycrystalline silicon (LTPS) TFT gate driver circuit, or an oxide semiconductor TFT gate driver circuit (OSG) built in the display panel DP. The scan driver SDV may be to receive a control signal from the controller 112-1 and output scan signals to the display panel DP in response to the control signal.

The display panel DP may further include an emission driver. The emission driver may be to output an emission control signal to the display panel DP in response to a control signal received from the controller 112-1. The emission driver may be formed or arranged separately from the scan driver SDV or may be integrated into the scan driver SDV.

The data driver DDV may be to receive a control signal from the controller 112-1, convert image data into an analog voltage (for example, a data voltage) in response to the control signal, and then output the data voltages to the display panel DP.

The data driver DDV may be integrated into another component (for example, the controller 112-1). A function of the interface conversion circuit and the timing control circuit of the controller 112-1 as described in one or more embodiments may be integrated into the data driver DDV.

The display module DM may further include the emission driver, a voltage generation circuit, and/or the like. The voltage generation circuit may be to output one or more suitable voltages desired or required to drive the display panel DP.

The power module 150 may be to supply power to components of the electronic device ED. The power module 150 may include a battery that charges a power voltage. The battery may include a non-rechargeable primary cell, a rechargeable secondary cell, and/or a fuel cell. The power module 150 may include a power management integrated circuit (PMIC). The PMIC may be to supply improved (or enhanced) or optimized power to each of the modules as described in one or more embodiments. The power module 150 may include a wireless power transmission/reception member electrically connected to the battery. The wireless power transmission/reception member may include a plurality of antenna radiators of a coil form.

The electronic device ED may further include the internal module 160 and the external module 170. The internal module 160 may include the sensor module 161, the antenna module 162, and the audio output module 163. The external module 170 may include a camera module 171, a light module 172, and the communication module 173.

The sensor module 161 may be to sense an input by a body of the user or an input by a pen of the first input module 131 and may be to generate an electrical signal or a data value corresponding to the input. The sensor module 161 may include at least one selected from among a fingerprint sensor 161-1, an input sensing layer 161-2, and a digitizer 161-3.

The fingerprint sensor 161-1 may be to generate a data value corresponding to a fingerprint of the user. The fingerprint sensor 161-1 may include any one selected from an optical type (kind) fingerprint sensor and/or a capacitive type (kind) fingerprint sensor.

The input sensing layer 161-2 may be to generate a data value corresponding to coordinate information of the input by the body of the user or the input by the pen. The input sensing layer 161-2 may be to generate the data value based on the change in capacitance caused by the input. The input sensing layer 161-2 may be to sense an input by the passive pen or may be to transmit/receive data to and from the active pen.

The input sensing layer 161-2 may be to measure a biometric signal, such as blood pressure, hydration levels, and/or body fat. For example, if (e.g., when) the user touches a part of their body to a sensor layer and/or a sensing panel and remains still for a certain (e.g., set or predetermined) period, the input sensing layer 161-2 may be to sense the biometric signal based on changes in an electric field caused by the body part and output information desired or suitable by the user to the display module DM.

The digitizer 161-3 may be to generate a data value corresponding to coordinate information of the input by the pen. The digitizer 161-3 may be to generate the data value based on changes in an electromagnetic field caused by the input. The digitizer 161-3 may be to sense the input by the passive pen or may be to transmit/receive data to and from the active pen.

At least one selected from among the fingerprint sensor 161-1, the input sensing layer 161-2, and the digitizer 161-3 may be implemented as a sensor layer formed or arranged on the display panel DP through a substantially continuous process. The fingerprint sensor 161-1, the input sensing layer 161-2, and the digitizer 161-3 may be arranged above the display panel DP, or any one selected from among the fingerprint sensor 161-1, the input sensing layer 161-2, and the digitizer 161-3, for example, the digitizer 161-3 may be arranged below the display panel DP.

At least two selected from among the fingerprint sensor 161-1, the input sensing layer 161-2, and the digitizer 161-3 may be integrated into a single sensing panel through substantially the same process. If (e.g., when) at least two selected from among the fingerprint sensor 161-1, the input sensing layer 161-2, and the digitizer 161-3 are integrated into one sensing panel, the sensing panel may be arranged between the display panel DP and the window arranged above the display panel DP. According to one or more embodiments, the sensing panel may be arranged on the window, and a position of the sensing panel should not be limited.

At least one selected from among the fingerprint sensor 161-1, the input sensing layer 161-2, and the digitizer 161-3 may be embedded in the display panel DP. For example, at least one selected from among the fingerprint sensor 161-1, the input sensing layer 161-2, and the digitizer 161-3 may be concurrently (e.g., simultaneously) formed or arranged through a process of forming or arranging elements (for example, a light emitting element, a transistor, and/or the like) included in the display panel DP.

In one or more embodiments, the sensor module 161 may be to generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 162 may include one or more antennas to transmit a signal or power to an external source or to receive a signal or power from an external source. According to one or more embodiments, the communication module 173 may be to transmit a signal to an external electronic device or may be to receive a signal from an external electronic device through an antenna suitable for a communication method. An antenna pattern of the antenna module 162 may be integrated into one component (for example, the display panel DP) of the display module DM or the input sensing layer 161-2.

The audio output module 163 may be a device to output an audio signal to an outside of the electronic device ED and, for example, may include a speaker used for general purposes, such as multimedia playback and/or recording playback, and a receiver used exclusively to receive a phone call. According to one or more embodiments, the receiver may be formed or arranged integrally with or separately from the speaker. An audio output pattern of the audio output module 163 may be integrated into the display module DM.

The camera module 171 may be to capture a still image and/or a video. According to one or more embodiments, the camera module 171 may include one or more lenses, an image sensor, or an image signal processor. The camera module 171 may further include an infrared camera capable of measuring presence or absence of the user, a position of the user, a line of sight of the user, and/or the like.

The light module 172 may be to provide light. The light module 172 may include a light emitting diode and/or a xenon lamp. The light module 172 may be to operate in conjunction with the camera module 171 or may operate independently.

The communication module 173 may be to support the establishment of a wired communication channel and/or a wireless communication channel between the electronic device ED and the external electronic device 102 and the communication through the established communication channel. The communication module 173 may include one or both (e.g., simultaneously) of a wireless communication module, such as a cellular communication module, a short-range wireless communication module, and/or a global navigation satellite system (GNSS) communication module, and a wired communication module, such as a local area network (LAN) communication module and/or a power line communication module. The communication module 173 may be to communicate with the external electronic device 102 through a short-range communication network, such as Bluetooth, WiFi direct, and/or infrared data association (IrDA), and/or a long-range communication network, such as a cellular network, the Internet, and/or a computer network (for example, LAN or WAN). The one or more suitable types (kinds) of communication modules 173 as described in one or more embodiments may be implemented as a single chip or as separate chips.

The input module 130, the sensor module 161, the camera module 171, and/or the like may be used in conjunction with the processor 110 to control an operation of the display module DM.

The processor 110 may be to output commands or data to the display module DM, the audio output module 163, the camera module 171, and/or the light module 172 based on input data received from the input module 130. For instance, the processor 110 may be to generate image data in response to the input data applied through the mouse, the active pen, and/or the like and output the image data to the display module DM or may be to generate command data in response to the input data and output the command data to the camera module 171 or the light module 172. If (e.g., when) no input data is received from the input module 130 for a certain (e.g., set or predetermined) period of time, the processor 110 may switch the operation mode of the electronic device ED to a low power mode or a sleep mode to reduce power consumed in the electronic device ED.

The processor 110 may be to output commands or data to the display module DM, the audio output module 163, the camera module 171, or the light module 172 based on sensing data received from the sensor module 161. For instance, the processor 110 may be to compare authentication data applied by the fingerprint sensor 161-1 with authentication data stored in the memory 120 and then execute an application according to a comparison result. The processor 110 may be to execute the command based on sensing data sensed by the input sensing layer 161-2 or the digitizer 161-3 or may be to output image data corresponding to the sensing data to the display module DM. If (e.g., when) the sensor module 161 includes a temperature sensor, the processor 110 may receive temperature data measured by the sensor module 161 and further perform luminance correction and/or the like on the image data based on the temperature data.

The processor 110 may be to receive measurement data regarding the presence or absence of the user, the position of the user, the gaze of the user, and/or the like, from the camera module 171. The processor 110 may further be to perform luminance correction and/or the like on the image data based on the measurement data. For instance, if (e.g., when) the processor 110 determines the presence or absence of the user through an input from the camera module 171, the processor 110 may output image data whose luminance is corrected through the data conversion circuit 112-2 or the gamma correction circuit 112-3 to the display module DM.

Among the components as described in one or more embodiments, one or more suitable components may be connected to each other through a communication method between peripheral devices, for example, a bus, general purpose input/output (GPIO), a serial peripheral interface (SPI), a mobile industry processor interface (MIPI), or an ultra-path interconnect (UPI) link to exchange a signal (for example, commands or data) with each other. The processor 110 may be to communicate with the display module DM through a mutually agreed interface, for example, any one selected from among the communication methods as described in one or more embodiments, and the communication method should not be limited to the communication methods as described in one or more embodiments.

The electronic device ED according to one or more embodiments of the present disclosure may be applied to one or more suitable types (kinds) of devices. The electronic device ED may include, for example, at least one selected from among a portable communication device (e.g., a smartphone), a computer device, a portable multimedia device, a portable medical device, a camera, a wearable device, and a home appliance device. The electronic device ED according to one or more embodiments of the present disclosure should not be limited to the devices as described in one or more embodiments.

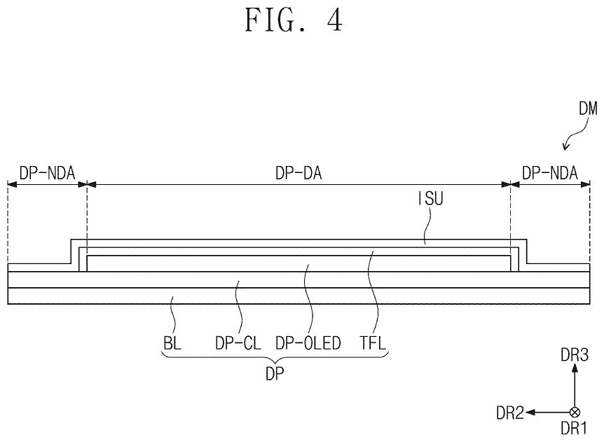

FIG. 4 is a cross-sectional view of the display module according to one or more embodiments of the present disclosure.

Referring to FIG. 4, the display module DM may include the display panel DP and the input sensing layer ISU arranged on the display panel DP.

The display panel DP may include a base layer BL, a circuit element layer DP-CL arranged on the base layer BL, a display element layer DP-OLED arranged on the circuit element layer DP-CL, and an encapsulation layer TFL arranged on the display element layer DP-OLED.

The display panel DP may include the display area DP-DA and the non-display area DP-NDA. The display area DP-DA of the display panel DP may correspond to the display area DD-DA (refer to FIG. 1) or the transmission area TA (refer to FIG. 2A), and the non-display area DP-NDA of the display panel DP may correspond to the non-display area DD-NDA (refer to FIG. 1) and the non-transmission area NTA (refer to FIG. 2A).

The base layer BL may include at least one plastic film. The base layer BL may be a flexible substrate and may include a plastic substrate, a glass substrate, a metal substrate, and/or an organic/inorganic composite material substrate.

The circuit element layer DP-CL may include insulating (e.g., electrically insulating) layers and a circuit element.

The insulating layer may be provided in plural. The insulating layers may include an inorganic layer and/or an organic layer.

The circuit element may include signal lines and a pixel driving circuit. The insulating layer, a semiconductor layer, and a conductive (e.g., electrically conductive) layer may be formed or arranged by coating and/or deposition processes. Then, the insulating layer, the semiconductor layer, and the conductive layer may be selectively patterned by a photolithography process and/or an etching process.

A semiconductor pattern, a conductive (e.g., electrically conductive) pattern, and the signal line may be formed or arranged through the process as described in one or more embodiments. Patterns arranged on substantially the same layer may be formed or arranged through substantially the same process. The expression “the patterns are formed or arranged through substantially the same process”, as used herein, refers to that the patterns include substantially the same material and have substantially the same stack structure.

The display element layer DP-OLED may include light emitting elements. The display element layer DP-OLED may further include an organic layer, such as a pixel definition layer.

The encapsulation layer TFL may encapsulate the display element layer DP-OLED. The encapsulation layer TFL may be arranged on the display element layer DP-OLED. The encapsulation layer TFL may overlap the display area DP-DA and the non-display area DP-NDA. The encapsulation layer TFL may overlap at least a portion of the non-display area DP-NDA.

The encapsulation layer TFL may have a stack structure of an inorganic layer, an organic layer, and an inorganic layer. The encapsulation layer TFL may protect the display element layer DP-OLED from moisture, oxygen, and/or a foreign substance, such as dust particles.

The input sensing layer ISU may be arranged directly on the display panel DP. In one or more embodiments, the input sensing layer ISU may be formed or arranged through a substantially continuous process on the display panel DP. However, embodiments of the present disclosure are not limited thereto. As an alternative example, the input sensing layer ISU may be provided as an individual panel and then may be coupled with the display panel DP by an adhesive layer.

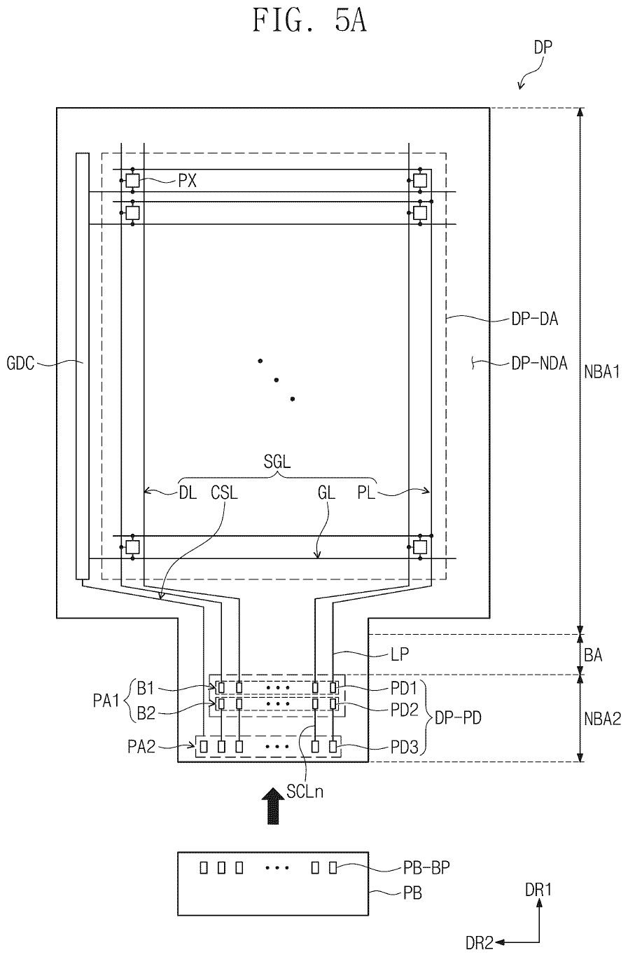

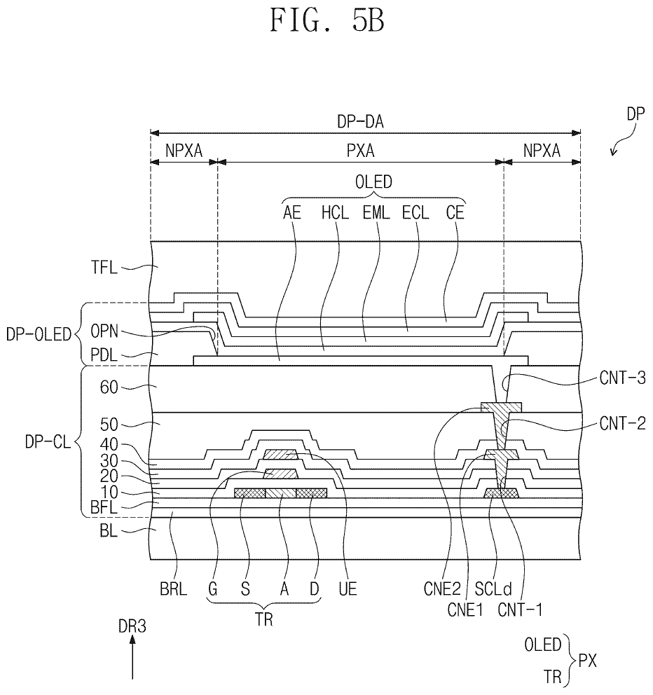

FIG. 5A is a plan view of the display panel according to one or more embodiments of the present disclosure.

Referring to FIG. 5A, the display panel DP may include a plurality of pixels PX, a gate driving circuit GDC, a plurality of signal lines SGL, and a plurality of signal pads DP-PD.

The pixels PX may be arranged in the display area DP-DA. Each of the pixels PX may include the light emitting element and the pixel driving circuit connected to the light emitting element. In one or more embodiments, the light emitting element may be an organic light emitting element.

The gate driving circuit GDC may be to sequentially output gate signals to a plurality of gate lines GL as described in more detail herein. The gate driving circuit GDC may include a transistor formed or arranged through substantially the same process, e.g., a low temperature polycrystalline silicon (LTPS) process and/or a low temperature polycrystalline oxide (LTPO) process, as a transistor of the pixel PX. The display panel DP may further include another driving circuit to apply an emission control signal to the pixels PX.

The signal lines SGL may include the gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may be to provide control signals to the gate driving circuit GDC.

The signal lines SGL may overlap the display area DP-DA and the non-display area DP-NDA. Each of the signal lines SGL may include a line part LP. The signal lines SGL may further include a pad part. The line part LP may overlap the display area DP-DA and the non-display area DP-NDA. The pad part may be connected to an end of the line part LP.

The signal pads DP-PD may include first pads PD1, second pads PD2, and third pads PD3.

In the present disclosure, an area in which the first pads PD1 and the second pads PD2 are arranged may be referred to as a first pad area PA1, and an area in which the third pads PD3 are arranged may be referred to as a second pad area PA2.

The first pad area PA1 may be an area the driving chip DC (refer to FIG. 2A) overlaps the display panel DP. The second pad area PA2 may be an area in which the circuit board PB (refer to FIG. 2A) overlaps the display panel DP.

The first pad area PA1 and the second pad area PA2 may be arranged in the non-display area DP-NDA. The first pad area PA1 and the second pad area PA2 may be spaced and/or apart (e.g., spaced apart or separated) from each other in first direction DR1. The first pad area PA1 may include a first area B1 in which the first pads PD1 are arranged and a second area B2 in which the second pads PD2 are arranged.

In the present disclosure, the first pad area PA1 or the second pad area PA2 may be referred to as a pad area. For example, the pad area may refer to at least one selected from among the first pad area PA1 and the second pad area PA2.

FIG. 5A illustrates two pad rows arranged in the first pad area PA1 and one pad row arranged in the second pad area PA2. However, the number of the pad rows arranged in each of the pad areas PA1 and PA2 should not be limited.

Each of the first pads PD1 may be connected to a corresponding data line DL among the data lines DL. In one or more embodiments, the first pads PD1 may be electrically connected to the second pads PD2. The second pads PD2 may be connected to the third pads PD3 through connection signal lines SCLn.

The circuit board PB may include substrate bumps PB-BP. The substrate bumps PB-BP may be arranged in the second direction DR2. The substrate bumps PB-BP of the circuit board PB may be in contact with the third pads PD3 of the second pad area PA2.

FIG. 5B is a cross-sectional view of the display panel according to one or more embodiments of the present disclosure.

FIG. 5B illustrates a cross-sectional view of one pixel PX (refer to FIG. 5A) of the display panel DP.

Referring to FIG. 5B, the display area DP-DA may include a light emitting area PXA and a non-light-emitting area NPXA adjacent to the light emitting area PXA.

Each of the pixels PX (refer to FIG. 5A) may include the light emitting element OLED and the pixel driving circuit connected to the light emitting element OLED. For example, the pixel PX (refer to FIG. 5A) may include the light emitting element OLED and the transistor TR.

FIG. 5B illustrates only one transistor TR included in the pixel PX (refer to FIG. 5A) as an example, however, embodiments of the present disclosure are not limited thereto. As an example, the pixel PX may include seven transistors and at least one capacitor, and the seven transistors and the capacitor may be electrically connected to each other. However, the number of the transistors and the number of the capacitors, which form the pixel PX, should not be limited.

The display panel DP may include a plurality of insulating (e.g., electrically insulating) layers, a semiconductor pattern, a conductive (e.g., electrically conductive) pattern, and a signal line. An insulating (e.g., electrically insulating) layer, a semiconductor layer, and a conductive (e.g., electrically conductive) layer may be formed or arranged by coating and/or deposition processes. Then, the insulating layer, the semiconductor layer, and the conductive layer may be selectively patterned by a photolithography process. The semiconductor pattern, the conductive pattern, and the signal line, which are included in the circuit element layer DP-CL and the display element layer DP-OLED, may be formed or arranged by the method as described in one or more embodiments.

The base layer BL may include a synthetic resin film. The base layer BL may have a multi-layer structure. For instance, the base layer BL may have a three-layer structure of a synthetic resin layer, an inorganic layer, and a synthetic resin layer. The synthetic resin layer may include a polyimide-based resin, however, embodiments of the present disclosure are not limited thereto. The base layer BL may include a glass substrate, a metal substrate, and/or an organic/inorganic composite substrate.

The circuit element layer DP-CL may include a barrier layer BRL, a buffer layer BFL, a first insulating layer 10, a second insulating layer 20, a third insulating layer 30, a fourth insulating layer 40, a fifth insulating layer 50, a sixth insulating layer 60, a transistor TR, a connection signal line SCLd, an upper electrode UE, a first connection electrode CNE1, and a second connection electrode CNE2.

The barrier layer BRL may be arranged on the base layer BL. The buffer layer BFL may be arranged on the barrier layer BRL. Each of the barrier layer BRL and the buffer layer BFL may be an inorganic layer.

The semiconductor pattern may be arranged on the buffer layer BFL. The semiconductor pattern may include polycrystalline silicon, however, embodiments of the present disclosure are not limited thereto. According to one or more embodiments, the semiconductor pattern may include an amorphous (e.g., non-crystalline) silicon and/or metal oxide.

FIG. 5B illustrates a portion of the semiconductor pattern, and the semiconductor pattern may be further arranged in other areas of the pixel PX if (e.g., when) viewed on a plane (e.g., in plan view). The semiconductor pattern may be arranged with a specific (e.g., set or predetermined) rule over the pixels PX. The semiconductor pattern may have different electrical properties depending on whether it is doped or not. The semiconductor pattern may include a first region and a second region. The first region may be doped with a negative type (kind) dopant (e.g., an N-type (kind) dopant) or a positive type (kind) (e.g., a P-type (kind) dopant). A positive type (kind) transistor (e.g., a P-type (kind) transistor) may include a doped area doped with the P-type (kind) dopant.

The first region may have a conductivity (e.g., electrical conductivity) greater than a conductivity (e.g., electrical conductivity) of the second region and may substantially act or serve as an electrode or a signal line. The second region may be a non-doped region or a region doped at a concentration lower than a concentration of the first region and may substantially correspond to an active (or a channel) of the transistor. A portion of the semiconductor pattern may be the active of the transistor, another portion of the semiconductor pattern may be a source or a drain of the transistor, and the other portion of the semiconductor pattern may be a connection electrode or a connection signal line.

As illustrated in FIG. 5B, a source S, an active A, and a drain D of the transistor TR may be formed or arranged from the semiconductor pattern.

FIG. 5B illustrates a portion of a connection signal line SCLd formed or arranged from the semiconductor pattern. The connection signal line SCLd may be electrically connected to a drain of one selected from among the transistors of the pixel PX.

The first insulating layer 10 may be arranged on the buffer layer BFL. The first insulating layer 10 may cover the semiconductor pattern. The first insulating layer 10 may commonly overlap the pixels. A gate G may be arranged on the first insulating layer 10. The gate G may be a portion of a metal pattern. The gate G may overlap the active A. The gate G may be used as a mask in a process of doping the semiconductor pattern.

The second insulating layer 20 may be arranged on the first insulating layer 10 and may cover the gate G. The second insulating layer 20 may commonly overlap the pixels. The upper electrode UE may be arranged on the second insulating layer 20. The upper electrode UE may overlap the gate G of the transistor TR. The upper electrode UE may be a portion of a metal pattern. A portion of the gate G and the upper electrode UE overlapping the portion of the gate G may define a capacitor.

The third insulating layer 30 may be arranged on the second insulating layer 20 and may cover the upper electrode UE. The first connection electrode CNE1 arranged on the third insulating layer 30 may be connected to the connection signal line SCLd via a contact hole CNT-1 defined through the first, second, and third insulating layers 10, 20, and 30.

The fourth insulating layer 40 may be arranged on the third insulating layer 30 and may cover the first connection electrode CNE1. The first to fourth insulating layers 10 to 40 may be an inorganic layer and/or an organic layer and may have a single-layer or multi-layer structure.

The fifth insulating layer 50 may be arranged on the fourth insulating layer 40. The fifth insulating layer 50 may be an organic layer. The second connection electrode CNE2 may be arranged on the fifth insulating layer 50. The second connection electrode CNE2 may be connected to the first connection electrode CNE1 via a contact hole CNT-2 defined through the fourth and fifth insulating layers 40 and 50.

The sixth insulating layer 60 may be arranged on the fifth insulating layer 50 and may cover the second connection electrode CNE2. The sixth insulating layer 60 may be an organic layer. A first electrode AE may be arranged on the sixth insulating layer 60. The first electrode AE may be connected to the second connection electrode CNE2 via a contact hole CNT-3 defined through the sixth insulating layer 60.

The display element layer DP-OLED may include a pixel definition layer PDL and the light emitting element OLED. A pixel opening OPN may be defined through the pixel definition layer PDL. At least a portion of the first electrode AE may be exposed through the pixel opening OPN of the pixel definition layer PDL. In one or more embodiments, the light emitting area PXA may be defined to correspond to a portion of the first electrode AE, which is exposed through the pixel opening OPN.

A hole control layer HCL may be commonly arranged in the light emitting area PXA and the non-light-emitting area NPXA. The hole control layer HCL may include a hole transport layer and may further include a hole injection layer. The light emitting layer EML may be arranged on the hole control layer HCL. The light emitting layer EML may be arranged in an area corresponding to the pixel opening OPN. For example, the light emitting layer EML may be divided into portions, and the divided portions of the light emitting layer EML may be respectively arranged in the pixels, however, embodiments of the present disclosure are not limited thereto. According to one or more embodiments, the light emitting layer EML may be commonly formed or arranged over the plural pixels PX utilizing an open mask.

An electron control layer ECL may be arranged on the light emitting layer EML. The electron control layer ECL may include an electron transport layer and may further include an electron injection layer. The hole control layer HCL and the electron control layer ECL may be commonly formed or arranged over the plural pixels PX utilizing an open mask. A second electrode CE may be arranged on the electron control layer ECL. The second electrode CE may have an integral shape (e.g., a substantially integral shape) and may be commonly arranged in the pixels.

The encapsulation layer TFL may be arranged on the second electrode CE. In one or more embodiments, the encapsulation layer TFL may have a structure in which an inorganic layer and an organic layer are alternately stacked with each other. Accordingly, oxygen and/or moisture entering the light emitting element OLED may be effectively or suitably blocked (or a degree to or occurrence of which oxygen and/or moisture entering the light emitting element OLED may be effectively or suitably reduced).

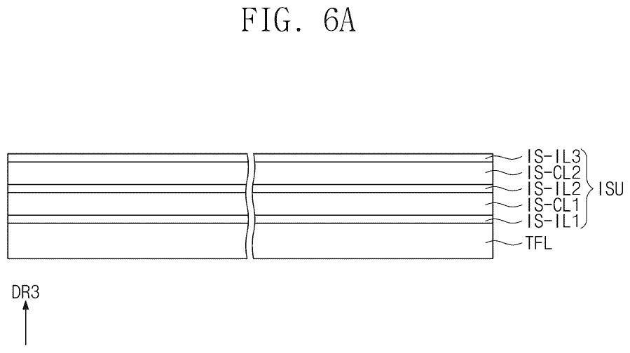

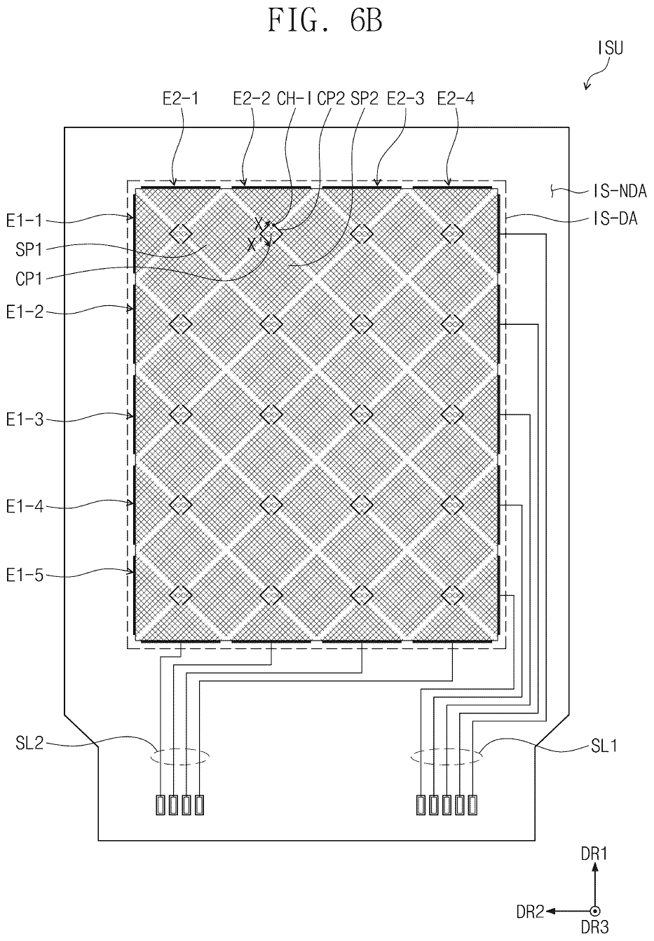

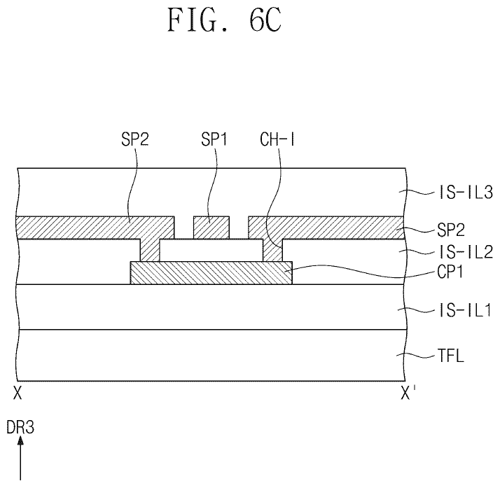

FIG. 6A is a cross-sectional view of the input sensing layer according to one or more embodiments of the present disclosure. FIG. 6B is a plan view of the input sensing layer according to one or more embodiments of the present disclosure. FIG. 6C is a cross-sectional view of an input sensing layer taken along the line X-X′ of FIG. 6B.

FIG. 6C is a cross-sectional view of a bridge pattern of the input sensing layer ISU according to one or more embodiments of the present disclosure, and the bridge pattern will be described in more detail herein.

The input sensing layer ISU may include a first sensing insulating layer IS-IL1, a second sensing insulating layer IS-IL2, and a third sensing insulating layer IS-IL3, a first sensing conductive layer IS-CL1 arranged between the first sensing insulating layer IS-IL1 and the second sensing insulating layer IS-IL2, and a second sensing conductive layer IS-CL2 arranged between the second sensing insulating layer IS-IL2 and the third sensing insulating layer and IS-IL3.

The first sensing insulating layer IS-IL1 may be arranged directly on the encapsulation layer TFL.

The first sensing conductive layer IS-CL1 may include first sensing conductive (e.g., electrically conductive) layers, and the second sensing conductive layer IS-CL2 may include second sensing conductive (e.g., electrically conductive) layers. Hereinafter, the first sensing conductive layer IS-CL1 and the first sensing conductive layers may be assigned with the same reference numeral, and the second sensing conductive layer IS-CL2 and the second sensing conductive layers may be assigned with the same reference numeral.

Each of the first sensing conductive layers IS-CL1 and the second sensing conductive layers IS-CL2 may have a single-layer structure or a multi-layer structure of layers stacked in the third direction DR3. The conductive pattern having the multi-layer structure may include two or more of the transparent (e.g., substantially transparent) conductive (e.g., electrically conductive) layers and the metal layers. The conductive pattern having the multi-layer structure may include metal layers containing different metals from each other. The transparent conductive layer may include one selected from among indium tin oxide (ITO), indium zinc oxide (IZO), zinc oxide (e.g., ZnOₓ, wherein 0<x≤2; e.g., ZnO), indium tin zinc oxide (ITZO), poly(3,4-ethylenedioxythiophene) (PEDOT), metal nanowire, and/or graphene. The metal layer may include one selected from among molybdenum, silver, titanium, copper, aluminum, and alloys thereof.

In one or more embodiments, each of the first sensing insulating layer IS-IL1, the second sensing insulating layer IS-IL2, and the third sensing insulating layer IS-IL3 may include an inorganic layer and/or an organic layer. In one or more embodiments, each of the first sensing insulating layer IS-IL1, the second sensing insulating layer IS-IL2, and the third sensing insulating layer IS-IL3 may include the inorganic layer. The inorganic layer may include silicon oxide, silicon nitride, and/or silicon oxynitride.

According to one or more embodiments, at least one selected from among the first sensing insulating layer IS-IL1, the second sensing insulating layer IS-IL2, and the third sensing insulating layer IS-IL3 may be an organic layer. For instance, the third sensing insulating layer IS-IL3 may include the organic layer. The organic layer may include at least one selected from among an acrylic-based resin, a methacrylic-based resin, a polyisoprene,-based resin, a vinyl-based resin, an epoxy-based resin, a urethane-based resin, a cellulose-based resin, a siloxane-based resin, a polyimide-based resin, a polyamide-based resin, and a perylene-based resin.

Referring to FIGS. 6B and 6C, the input sensing layer ISU may include a sensing area IS-DA and a non-sensing area IS-NDA adjacent to the sensing area IS-DA.

The sensing area IS-DA and the non-sensing area IS-NDA may correspond to the display area DP-DA and the non-display area DP-NDA as illustrated in FIG. 4, respectively.

The input sensing layer ISU may include sensing electrodes E1-1 to E1-5 and E2-1 to E2-4 arranged in the sensing area IS-DA. The sensing electrodes E1-1 to E1-5 and E2-1 to E2-4 may include first electrodes E1-1 to E1-5 and second electrodes E2-1 to E2-4 insulated (e.g., electrically insulated) from the first electrodes E1-1 to E1-5 while crossing (e.g., intersecting) the first electrodes E1-1 to E1-5.

The input sensing layer ISU may include first signal lines SL1 arranged in the non-sensing area IS-NDA and electrically connected to the first electrodes E1-1 to E1-5 and second signal lines SL2 arranged in the non-sensing area IS-NDA and electrically connected to the second electrodes E2-1 to E2-4.

The first electrodes E1-1 to E1-5, the second electrodes E2-1 to E2-4, the first signal lines SL1, and the second signal lines SL2 may be defined by the first sensing conductive layers IS-CL1 and the second sensing conductive layers IS-CL2.

Each of the first electrodes E1-1 to E1-5 and the second electrodes E2-1 to E2-4 may include conductive (e.g., electrically conductive) lines crossing (e.g., intersecting) with each other. Openings may be defined by the conductive lines crossing (e.g., intersecting) with each other. Accordingly, each of the first electrodes E1-1 to E1-5 and the second electrodes E2-1 to E2-4 may define a mesh shape (e.g., a substantially mesh shape).

Each of the openings defined by the conductive lines may correspond to the pixel opening OPN (refer to FIG. 5) defined through the pixel definition layer PDL (refer to FIG. 5).

One selected from among the first electrodes E1-1 to E1-5 and the second electrodes E2-1 to E2-4 may have an integral shape (e.g., a substantially integral shape). FIG. 6B illustrates the structure in which each of the first electrodes E1-1 to E1-5 has the integral shape.

Each of the first electrodes E1-1 to E1-5 may include sensing portions SP1 and intermediate portions CP1. The sensing portions SP1 and the intermediate portions CP1 may be portions of the second sensing conductive layers IS-CL2 (refer to FIG. 6A). The sensing portions SP1 and the intermediate portions CP1 may be defined by the second sensing conductive layers IS-CL2 (refer to FIG. 6A).

Each of the second electrodes E2-1 to E2-4 may include sensing patterns SP2 and bridge patterns CP2. FIGS. 6B and 6C illustrate a structure in which two adjacent sensing patterns SP2 are connected to each other by two bridge patterns CP2 via a contact hole CH-I defined through the second sensing insulating layer IS-IL2 as an example. However, the number of the bridge patterns CP2 connecting the sensing patterns SP2 should not be limited.

The sensing patterns SP2 may be portions of the second sensing conductive layers IS-CL2 (refer to FIG. 6A). The bridge patterns CP2 may be portions of the first sensing conductive layers IS-CL1 (refer to FIG. 6A). The sensing patterns SP2 and the bridge patterns CP2 may be defined by the second sensing conductive layers IS-CL2 (refer to FIG. 6A) and the first sensing conductive layers IS-CL1 (refer to FIG. 6A).

However, embodiments of the present disclosure are not limited thereto. As an example, the first electrodes E1-1 to E1-5 and the sensing patterns SP2 may be defined by the first sensing conductive layers IS-CL1 (refer to FIG. 6A), and the bridge patterns CP2 may be defined by the second conductive patterns IS-CL2 (refer to FIG. 6A).

One selected from among the first signal lines SL1 and the second signal lines SL2 may be to receive a transmission signal to sense an external input from an external circuit. The other of the first signal lines SL1 and the second signal lines SL2 may be to transmit a variation in capacitance between the first electrodes E1-1 to E1-5 and the second electrodes E2-1 to E2-4 to the external circuit as a reception signal.

In one or more embodiments, the first signal lines SL1 and the second signal lines SL2 may be portions of the second conductive patterns IS-CL2. The first signal lines SL1 and the second signal lines SL2 may have a multi-layer structure and may include a first layer line formed or arranged from the first sensing conductive layers IS-CL1 and a second layer line formed or arranged from the second sensing conductive layers IS-CL2. The first layer line and the second layer line may be connected to each other via a contact hole defined through the second sensing insulating layer IS-IL2 (refer to FIG. 6A).

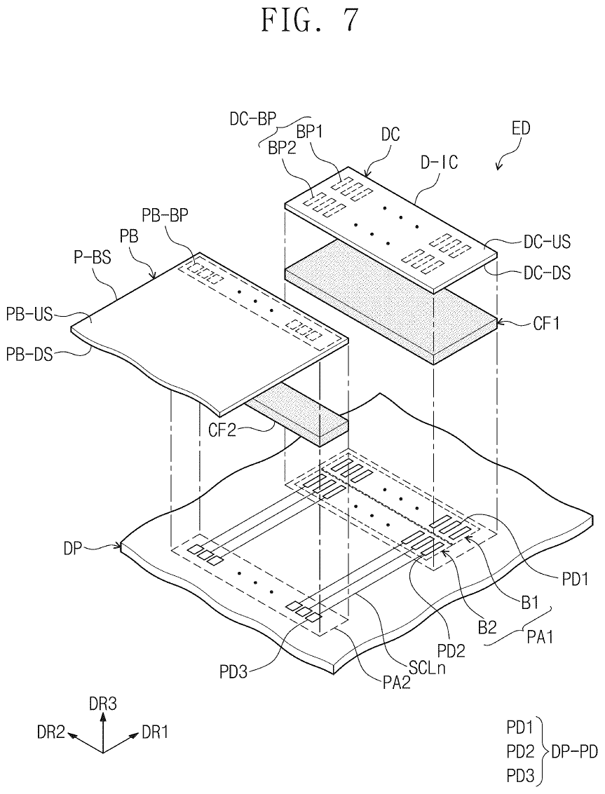

FIG. 7 is an enlarged exploded perspective view of the pad area of the electronic device according to one or more embodiments of the present disclosure.

FIG. 7 is an enlarged exploded perspective view of the pad areas PA1 and PA2 of the electronic device according to one or more embodiments of the present disclosure.

The driving chip DC may be bonded to the first pad area PA1 by a first adhesive layer CF1. The circuit board PB may be bonded to the second pad area PA2 by a second adhesive layer CF2. The adhesive layers CF1 and CF2 may be an anisotropic conductive film (ACF). Accordingly, the adhesive layers CF1 and CF2 may include a synthetic resin with an adhesive property and conductive (e.g., electrically conductive) balls. In the present disclosure, the adhesive layers CF1 and CF2 may be referred to as a conductive (e.g., electrically conductive) film.

The driving chip DC may include a driving integrated circuit D-IC and chip bumps DC-BP provided in the driving chip DC.

The driving integrated circuit D-IC may include an upper surface DC-US and a lower surface DC-DS. The lower surface DC-DS of the driving integrated circuit D-IC may be opposite to (e.g., face) the first and second pads PD1 and PD2.

The chip bumps DC-BP may be arranged on the lower surface DC-DS of the driving integrated circuit D-IC. The chip bumps DC-BP may include first bumps BP1 electrically connected to the first pads PD1, respectively, and second bumps BP2 electrically connected to the second pads PD2, respectively. The first bumps BP1 may be arranged in the second direction DR2, and the second bumps BP2 may be spaced and/or apart (e.g., spaced apart or separated) from the first bumps BP1 in the first direction DR1 and may be arranged in the second direction DR2.

The driving chip DC may be to receive first signals via the second pads PD2 and the second bumps BP2. The driving chip DC may be to generate second signals based on the first signals and may be to apply the second signals to the first pads PD1 via the first bumps BP1.

As an example, the driving chip DC may include a data driving circuit. The first signal may be an image signal that is a digital signal provided from the outside, and the second signal may be a data signal that is an analog signal. The driving chip DC may be to generate an analog voltage corresponding to a grayscale value of the image signal. The data signal may be applied to the pixels PX (refer to FIG. 5A) via the data line DL (refer to FIG. 5A).

In one or more embodiments, the first bumps BP1 and the second bumps BP2 may protrude from the lower surface DC-DS of the driving integrated circuit D-IC and may be exposed to the outside. If (e.g., when) the first adhesive layer CF1 is cured, the first pads PD1 may be attached and fixed to the first bumps BP1, and the second pads PD2 may be attached and fixed to the second bumps BP2.

The circuit board PB may include a base layer P-BS and the substrate bumps PB-BP provided in the circuit board PB.

The circuit board PB may include an upper surface PB-US and a lower surface PB-DS, and the lower surface PB-DS of the circuit board PB may be opposite to (e.g., face) the third pads PD3. The substrate bumps PB-BP may be arranged on the lower surface PB-DS of the base layer P-BS. The substrate bumps PB-BP may be electrically connected to the third pads PD3, respectively. The substrate bumps PB-BP may be arranged in the second direction DR2. The circuit board PB may provide image signals, driving voltages, and control signals to the driving chip DC.

In one or more embodiments, the substrate bumps PB-BP may protrude from the lower surface PB-DS of the base layer P-BS and may be exposed to the outside. If (e.g., when) the second adhesive layer CF2 is cured, the third pads PD3 may be attached and fixed to the substrate bumps PB-BP.

The electronic component may include a substrate and a bump arranged under the substrate. If (e.g., when) the electronic component corresponds to the driving chip DC, the substrate may correspond to the driving integrated circuit D-IC of the driving chip DC, and the bump may correspond to the chip bump DC-BP. According to one or more embodiments, if (e.g., when) the electronic component corresponds to the circuit board PB, the substrate may correspond to the base layer P-BS of the circuit board PB, and the bump may correspond to the substrate bump PB-BP.

However, each of the pads PD1, PD2, and PD3 may have a structure in which conductive (e.g., electrically conductive) patterns are stacked to be electrically connected to a corresponding bump of the bumps BP1, BP2, and BP3. However, the stacked conductive patterns may be curved due to the insulation layer with a step difference and thus may be peeled or detached. However, because the pads according to one or more embodiments of the present disclosure may include the structure in which the step difference is compensated, the conductive patterns may be prevented from being curved (or a degree to or occurrence of which the conductive patterns is curved may be reduced). Accordingly, the peeling or detachment phenomenon of the conductive patterns may be effectively or suitably prevented (or a degree or occurrence of the peeling or detachment phenomenon of the conductive patterns may be effectively or suitably reduced), and the reliability of the electronic device may be improved or enhanced.

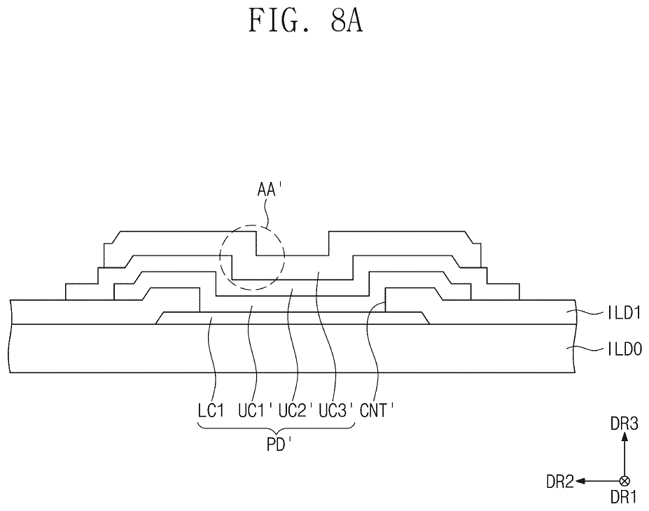

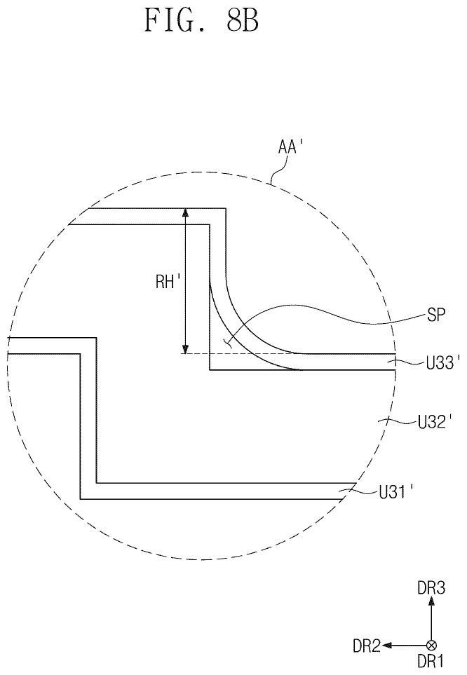

Hereinafter, the step-difference compensation structure of the present disclosure and its resulting effects will be described in more detail with reference to FIGS. 8A to 8B.

FIG. 8A is an enlarged cross-sectional view of a pad area of an electronic device according to a comparative example. FIG. 8B is an enlarged view of an area AA′ of FIG. 8A.

In FIGS. 8A and 8B, the pad area may correspond to at least one selected from among the first pad area PA1 and the second pad area PA2 as described with reference to FIG. 5A.

The comparative example as illustrated in FIGS. 8A and 8B may be an electronic device that is generally available or generally used.

Referring to FIG. 8A, the electronic device according to the comparative example may include a base insulating layer ILD0, a first insulating pattern ILD1 arranged on the base insulating layer ILD0, and a pad PD′ arranged on the base insulating layer ILD0.

The pad PD′ according to the comparative example may include a first lower conductive pattern LC1, a first upper conductive pattern UC1′, a second upper conductive pattern UC2′, and a third upper conductive pattern UC3′.

The first lower conductive pattern LC1 and the first, second, and third upper conductive patterns UC1′, UC2′, and UC3′ may be electrically connected to each other.

A contact hole CNT′ may be defined through an upper surface and a rear surface of the first insulating pattern ILD1. The first lower conductive pattern LC1 may be exposed through the contact hole CNT′ and may be in contact with the first upper conductive pattern UC1′.

In one or more embodiments, the step difference may sequentially occur in the first, second, and third upper conductive patterns UC1′, UC2′, and UC3′ due to the contact hole CNT′ defined through the first insulating layer ILD1. For example, due to a difference in height between the upper surface of the first insulating layer ILD1 and an upper surface of the first lower conductive pattern LC1, a curvature may occur in the first upper conductive pattern UC1′. In the present disclosure, a phenomenon in which the curvature occurs may be referred to as a reverse tapered phenomenon.

In one or more embodiments, the curvature may occur in the second upper conductive pattern UC2′ due to the curvature of the first upper conductive pattern UC1′, and the curvature may also occur in the third upper conductive pattern UC3′ due to the curvature of the second upper conductive pattern UC2′. FIG. 8A illustrates the curvature occurring in the third upper conductive pattern UC3′ in the area AA′.

FIG. 8B is an enlarged cross-sectional view of the area AA′ of FIG. 8A. FIG. 8B is an enlarged cross-sectional view of a portion of the third upper conductive pattern UC3′ where the curvature occurs.

Referring to FIG. 8B, the third upper conductive pattern UC3′ may include a plurality of layers. In more detail, the third upper conductive pattern UC3′ may include a third-first upper conductive pattern U31′, a third-second upper conductive pattern U32′, and a third-third upper conductive pattern U33′. Each of the third-first to third-third upper conductive patterns U31′ to U33′ may have a structure in which layers respectively containing titanium/aluminum/titanium are sequentially stacked.

FIG. 8B illustrates a state in which the peeling phenomenon occurs due to a step difference RH′ of the third-third upper conductive pattern U33′, however, this is for the convenience of explanation. As an example, the peeling phenomenon may occur in the third-first and third-second upper conductive patterns U31′ and U32′ or in the first upper conductive pattern UC1 and the second upper conductive pattern UC1 (refer to FIG. 8A). In one or more embodiments, descriptions on the peeling phenomenon as described with reference to FIG. 8B may be equally applied to the first and second upper conductive patterns UC1 and UC2 (refer to FIG. 8A).

Referring to FIG. 8B, the peeling phenomenon may occur in the third-third upper conductive pattern U33′ due to the step difference RH′, and thus, a separation space SP may be formed or arranged between the third-second upper conductive pattern U32′ and the third-third upper conductive pattern U33′.

In the electronic device that is generally available or generally used, the third upper conductive pattern UC3′ may be oxidized by moisture/oxygen that infiltrates between the separation space SP. Accordingly, reliability in bonding of the pad PD′ (refer to FIG. 8A) may be deteriorated.

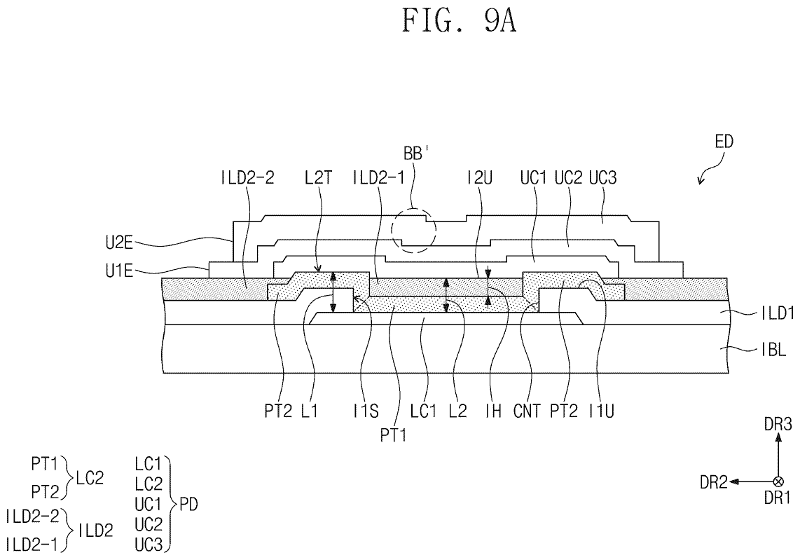

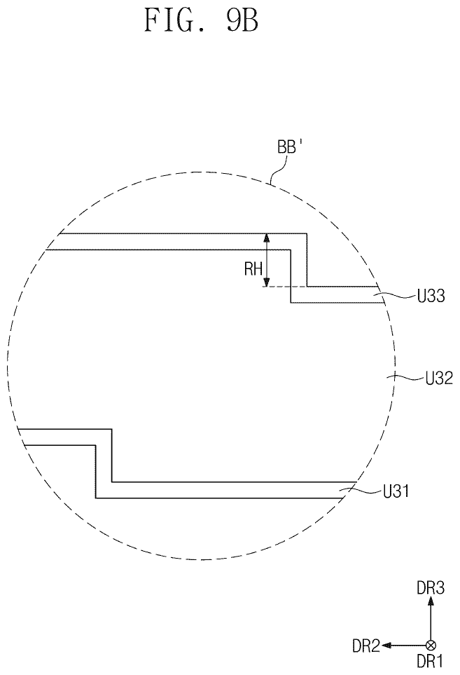

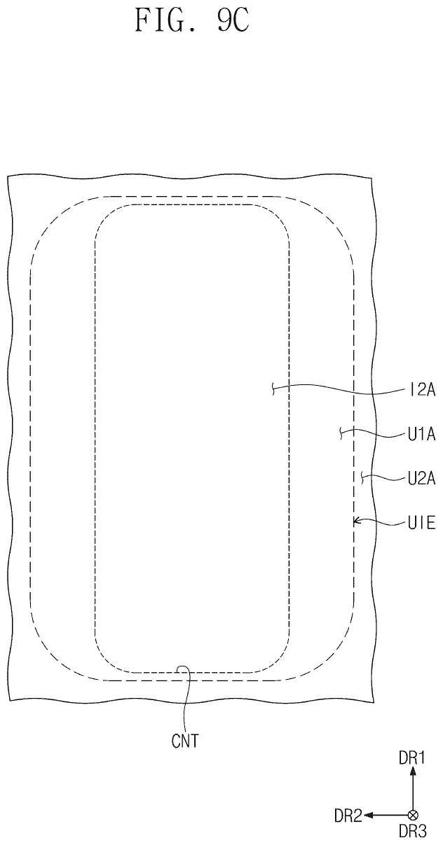

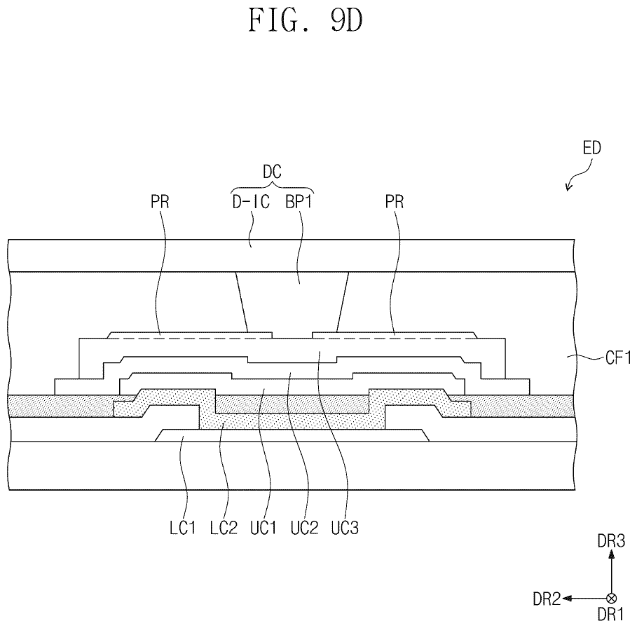

FIG. 9A is an enlarged cross-sectional view of a pad area of an electronic device according to one or more embodiments of the present disclosure. FIG. 9B is an enlarged view of an area BB′ of FIG. 9A.

In FIG. 9A, the pad area may correspond to at least one selected from among the first pad area PA1 and the second pad area PA2 as described with reference to FIG. 5A.

Referring to FIG. 9A, the electronic device according to one or more embodiments may include a base substrate IBL, a first insulating pattern ILD1 arranged on the base substrate IBL, a second insulating pattern ILD2 arranged on the first insulating pattern ILD1, and a pad PD. The base substrate IBL may be formed or arranged through substantially the same process as the base layer BL (refer to FIG. 5B) and may include substantially the same material as the base layer BL (refer to FIG. 5B) as described with reference to FIG. 5B.

However, for the convenience of explanation, components arranged between the base substrate IBL and a first lower conductive pattern LC1 may not be provided, and the present disclosure should not be limited to the electronic device ED as illustrated in FIG. 9A. One or more organic layers and/or inorganic layers may be arranged between the base substrate IBL and the first lower conductive pattern LC1.

The electronic device ED according to one or more embodiments of the present disclosure may further include the second insulating pattern ILD2 compared to the electronic device as described with reference to FIGS. 8A and 8B.

The pad PD according to one or more embodiments of the present disclosure may include a first lower conductive pattern LC1, a second lower conductive pattern LC2, a first upper conductive pattern UC1, a second upper conductive pattern UC2, and a third upper conductive pattern UC3. For example, the pad PD according to one or more embodiments of the present disclosure may further include the second lower conductive pattern LC2 compared to the pad PD′ as described with reference to FIGS. 8A and 8B.

The first lower conductive pattern LC1 may be arranged on the base substrate IBL. The first lower conductive pattern LC1 may be formed or arranged through substantially the same process as the gate G included in the transistor TR of the pixel PX (refer to FIG. 5A) and may include substantially the same materials as the gate G included in the transistor TR of the pixel PX (refer to FIG. 5A).

The first insulating pattern ILD1 may be arranged on the base substrate IBL. The first insulating pattern ILD1 may cover the first lower conductive pattern LC1. A contact hole CNT may be defined through upper and lower surfaces of the first insulating pattern ILD1. The contact hole CNT may be defined by a side surface I1S of the first insulating pattern ILD1.

If (e.g., when) viewed on a plane (e.g., in plan view), the contact hole CNT may overlap the first lower conductive pattern LC1. A portion of the first lower conductive pattern LC1 may be exposed through the contact hole CNT. Accordingly, the first lower conductive pattern LC1 may be connected to the second lower conductive pattern LC2.

The second lower conductive pattern LC2 may be arranged on the first insulating pattern ILD1 and the first lower electrode LC1. The second lower conductive pattern LC1 may be formed or arranged through substantially the same process as a gate included in another transistor of the pixel PX (refer to FIG. 5A) and may include substantially the same material as a gate included in another transistor of the pixel PX (refer to FIG. 5A).

The second lower conductive pattern LC2 may include a first portion PT1 and a second portion PT2. In FIG. 9A, the first portion PT1 and the second portion PT2 are illustrated as being separated by a diagonal dotted line parallel to the direction between the second direction DR2 and the third direction DR3. However, this is for the convenience of explanation, and the first portion PT1 and the second portion PT2 may be provided as a substantially continuous single unit. The second portion PT2 may extend from the first portion PT1 and may be provided integrally with the first portion PT1.

The first portion PT1 may cover the first lower conductive pattern LC1 exposed through the contact hole CNT. The first portion PT1 may be in contact with the first lower conductive pattern LC1. Accordingly, the second lower conductive pattern LC2 may be electrically connected to the first lower conductive pattern LC1.

The second portion PT2 may cover a side surface I1S and an upper surface I1U of the first insulating pattern ILD1. The second portion PT2 may be exposed without being covered by the second insulating pattern ILD2.

The second insulating pattern ILD2 may include a second-first insulating pattern ILD2-1 and a second-second insulating pattern ILD2-2.

The second-first insulating pattern ILD2-1 may be arranged on the first portion PT1. At least a portion of the second-first insulating pattern ILD2-1 may be arranged inside the contact hole CNT. The second-first insulating pattern ILD2-1 may prevent the step difference from occurring in the first upper conductive pattern UC1 (or reduce a degree to or occurrence of which the step difference occurs in the first upper conductive pattern UC1). In more detail, the second-first insulating pattern ILD2-1 may have a selected thickness IH, and thus, the step difference may be prevented from occurring in the first upper conductive pattern UC1 (or a degree to or occurrence of which the step difference occurs in the first upper conductive pattern UC1 may be reduced).

The first insulating pattern ILD1 and the second insulating pattern ILD2 may be formed or arranged through substantially the same process as one or more of the insulating layers 10 to 60 as described with reference to FIG. 5B and the sensing insulating layers IS-IL1 to IS-IL3 as described with reference to FIG. 6A and may include substantially the same material as one or more of the insulating layers 10 to 60 as described with reference to FIG. 5B and the sensing insulating layers IS-IL1 to IS-IL3 as described with reference to FIG. 6A. However, the first insulating pattern ILD1 may be formed or arranged after the first lower conductive pattern LC1 is formed or arranged, and the second insulating pattern ILD2 may be formed or arranged after the second lower conductive pattern LC2. In one or more embodiments, the first insulating pattern ILD1 and the second insulating pattern ILD2 may be formed or arranged before the first upper conductive pattern LC1 is formed or arranged.

The first upper conductive pattern UC1 may be arranged on the second-first insulating pattern ILD2-1.

The first upper conductive pattern UC1 may be spaced and/or apart (e.g., spaced apart or separated) from the first lower conductive pattern LC1.

The first upper conductive pattern UC1 may not be in contact with the first portion PT1. The first upper conductive pattern UC1 may be spaced and/or apart (e.g., spaced apart or separated) from the first portion PT1, and the second-first insulating pattern ILD2-1 may be arranged between the first upper conductive pattern UC1 and the first portion PT1, and thus, the first upper conductive pattern UC1 may not be in contact with the first portion PT1. Accordingly, the first upper conductive pattern UC1 may not be arranged inside the contact hole CNT.

However, the first upper conductive pattern UC1 may be in contact with the second portion PT2. For example, the second portion PT2 exposed without being covered by the second insulating pattern ILD2 may be in contact with the first upper conductive pattern UC1. An upper surface of the second portion PT2 may be in contact with the first upper conductive pattern UC1.

The first upper conductive pattern UC1 may be electrically connected to the first lower conductive pattern LC1 through the second lower conductive pattern LC2. For example, the step difference in the first upper conductive pattern UC1 may be compensated by the second-first insulating pattern ILD2-1. The first upper conductive pattern UC1 may be electrically connected to the first lower conductive pattern LC1.

The first upper conductive pattern UC1 may be arranged inside the contact hole CNT and may not be in direct contact with the first lower conductive pattern LC1, however, the first upper conductive pattern UC1 may be electrically connected to the first lower conductive pattern LC1 through the second portion PT2 on the first insulating pattern ILD1.

Therefore, the curvature due to the step difference may not occur in first upper conductive pattern UC1 or may be reduced. FIG. 9A illustrates the first upper conductive pattern UC1, which has significantly or substantially reduced curvature compared to the first upper conductive pattern UC1′ as described with reference to FIG. 8A.

The second upper conductive pattern UC2 may be arranged on the first upper conductive pattern UC1. The second upper conductive pattern UC2 may cover the first upper conductive pattern UC1. The shape of the second upper conductive pattern UC2 may be indirectly determined by the shape of the first upper conductive pattern UC1. For example, if (e.g., when) the curvature (e.g., a degree or occurrence of the curvature) of the first upper conductive pattern UC1 is reduced, the curvature (e.g., a degree or occurrence of the curvature) of the second upper conductive pattern UC2 may also be reduced.

The second upper conductive pattern UC2 may be in contact with the first upper conductive pattern UC1. The second upper conductive pattern UC2 may have an area greater than an area of the first upper conductive pattern UC1 if (e.g., when) viewed on a plane (e.g., in plan view).

Each of edges U2E of the second upper conductive pattern UC2 may be spaced and/or apart (e.g., spaced apart or separated) from the first insulating pattern ILD1, and the second-first insulating pattern ILD2-1 may be arranged between the first insulating pattern ILD1 and the edges U2E.

A distance L1 between an uppermost portion L2T of the second lower conductive pattern LC2 and an upper surface of the first lower conductive pattern LC1 may be greater than a distance L2 between an upper surface L2U of the second-first insulating pattern and the first lower conductive pattern LC1.

In one or more embodiments, the second insulating pattern ILD2 may further include the second-second insulating pattern ILD2-2. The second-second insulating pattern ILD2-2 may be arranged on the first insulating pattern ILD1 and may be spaced and/or apart (e.g., spaced apart or separated) from the second-first insulating pattern ILD2-1. The second-second insulating pattern ILD2-2 may cover the second lower conductive pattern LC2.

However, embodiments of the present disclosure are not limited thereto, and the second-second insulating pattern ILD2-2 may not be provided.

Each of the first and second upper conductive patterns UC1 and UC2 may include layers that are sequentially stacked in a direction away from the first lower conductive pattern LC1 and including a metal material.

The first upper conductive pattern UC1 may be formed or arranged through substantially the same process as one selected from among the signal lines SGL (refer to FIG. 5A) and the connection electrodes CNE1 and CNE2 (refer to FIG. 5B) and may include substantially the same material as one selected from among the signal lines SGL (refer to FIG. 5A) and the connection electrodes CNE1 and CNE2 (refer to FIG. 5B).

The second upper conductive pattern UC2 may be formed or arranged through substantially the same process as one selected from among the signal lines SGL (refer to FIG. 5A), the connection electrodes CNE1 and CNE2 (refer to FIG. 5B), and the first electrode AE (refer to FIG. 5A) and may include substantially the same material as one selected from among the signal lines SGL (refer to FIG. 5A), the connection electrodes CNE1 and CNE2 (refer to FIG. 5B), and the first electrode AE (refer to FIG. 5A). However, the first upper conductive pattern UC1 and the second upper conductive pattern UC2 may be formed or arranged through different processes from each other, and the first upper conductive pattern UC1 may be formed or arranged before the second upper conductive pattern UC2.

In one or more embodiments, each of the first and second upper conductive patterns UC1 and UC2 may include a first layer including titanium, a second layer including aluminum, and a third layer including titanium, wherein the first layer, the second layer, and the third layer are sequentially stacked in the third direction DR3.

The third upper conductive pattern UC3 may be arranged on the second upper conductive pattern UC2. The shape of the third upper conductive pattern UC3 may be indirectly determined by the shape of the second upper conductive pattern UC2. For example, if (e.g., when) the curvature (e.g., a degree or occurrence of the curvature) of the first upper conductive pattern UC1 is reduced, the curvature (e.g., a degree or occurrence of the curvature) of the second upper conductive pattern UC2 and the third upper conductive pattern UC3 may also be reduced.

In one or more embodiments, the third upper conductive pattern UC3 may be formed or arranged through a single process together with the second sensing conductive layer IS-CL2 and may include substantially the same material as the second sensing conductive layer IS-CL2, however, embodiments of the present disclosure are not limited thereto. As an example, the third upper conductive pattern UC3 may be formed or arranged through a single process together with the first sensing conductive layer IS-CL1 and may include substantially the same material as the first sensing conductive layer IS-CL1.

According to one or more embodiments, the third upper conductive pattern UC3 may include a first layer and a second layer arranged on the first layer. The first layer may be formed or arranged through a single process together with the first sensing conductive layer IS-CL1 and may include substantially the same material as the first sensing conductive layer IS-CL1. The second layer may be formed or arranged through a single process together with the second sensing conductive layer IS-CL2 and may include substantially the same material as the second sensing conductive layer IS-CL2.

FIG. 9B is an enlarged cross-sectional view of the area BB′ of FIG. 9A. Referring to FIG. 9B, the third upper conductive pattern UC3 may include a plurality of layers. In more detail, the third upper conductive pattern UC3 may include a third-first upper conductive pattern U31, a third-second upper conductive pattern U32, and a third-third upper conductive pattern U33. Each of the third-first to third-third upper conductive patterns U31 to U33 may have a structure in which layers respectively including titanium, aluminum, and titanium are sequentially stacked.

FIG. 9B illustrates a state in which the peeling phenomenon does not occur in the third-third upper conductive pattern U33 as an example. For example, a step difference RH in one or more embodiments of the present disclosure may be reduced compared to the step difference RH′ in the comparative example described with reference to FIG. 8B.

For example, according to the electronic device of the present disclosure, the occurrence of the curvature may be prevented or reduced by the second insulating pattern ILD2 (refer to FIG. 9A) and the second lower conductive pattern LC2 (refer to FIG. 9A), and the occurrence of the peeling phenomenon may be prevented or reduced. Accordingly, the conductivity (e.g., electrical conductivity) of the layers may be maintained, and the bonding reliability may be maintained.

FIG. 9C is an enlarged plan view of the pad area according to one or more embodiments of the present disclosure.

Hereinafter, for the convenience of explanation, an area where the second upper conductive pattern UC2 is arranged may be defined as a second upper area U2A, an area where the first upper conductive pattern UC1 is arranged may be defined as a first upper area U1A, and an area where the second-first insulating pattern ILD2-1 (refer to FIG. 9A) is arranged may be defined as an insulating area I2A.

Referring to FIG. 9C, the second upper area U2A may include the first upper area U1A if (e.g., when) viewed on a plane (e.g., in plan view). The first upper area U1A may include the insulating area I2A.

A boundary of the insulating area I2A may be defined by the contact hole CNT.

FIG. 9D is a cross-sectional view illustrating the bonding structure of the electronic device according to one or more embodiments of the present disclosure.

Hereinafter, the driving chip DC and the first bump BP1 will be described as examples of the electronic component and the bump, respectively, however, embodiments of the present disclosure are not limited thereto. Other electronic components except the driving chip DC as described with reference to FIG. 4 may be used as the electronic component. In one or more embodiments, descriptions on the first bump BP1 may be equally/similarly applied to the second bump BP2 (refer to FIG. 7) or the substrate bump PB-BP (refer to FIG. 7).

FIG. 9D illustrates a structure in which the first bump BP1 of the driving chip DC is in contact with the third upper conductive pattern UC3 as an example.

The first bump BP1 of the driving chip DC may be in contact with the third upper conductive pattern UC3 due to a bonding pressure after penetrating through the first adhesive layer CF1. Although the step difference is reduced, the third upper conductive pattern UC3 may include a protrusion portion PR protruded in the third direction DR3.

For the convenience of explanation, the protrusion portion PR formed or arranged in the third upper conductive pattern UC3 is represented by a dotted line in FIG. 9D.

In one or more embodiments, a conductive (e.g., electrically conductive) ball included in the first adhesive layer CF1 may be arranged between the protrusion portion PR of the third upper conductive pattern UC3 and the first bump BP1. Therefore, the first bump BP1 may secure an electrical connection path with the protrusion portion PR.

As described in one or more embodiments, according to the electronic device ED of the present disclosure, because the step difference may be compensated, the occurrence of the peeling phenomenon of the conductive pattern may be prevented or reduced, and the electrical contact between the conductive pattern and the bump may be maintained. Accordingly, the bonding reliability of the electronic device may be improved or enhanced, and reliability of the electronic device may be improved or enhanced.

The first bump BP1, the first, second, and third upper conductive patterns UC1, UC2, and UC3, and the first and second lower conductive patterns LC1 and LC2 may be electrically connected to each other.

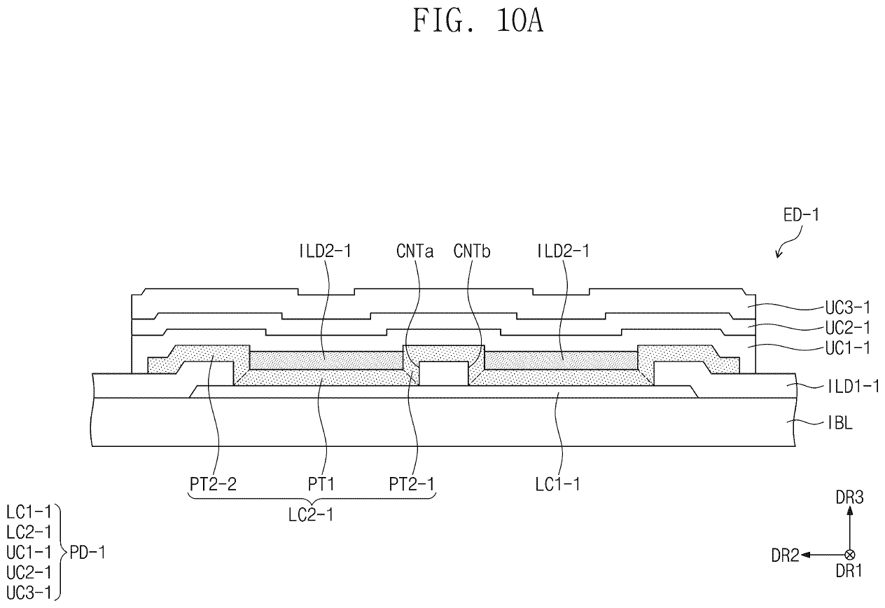

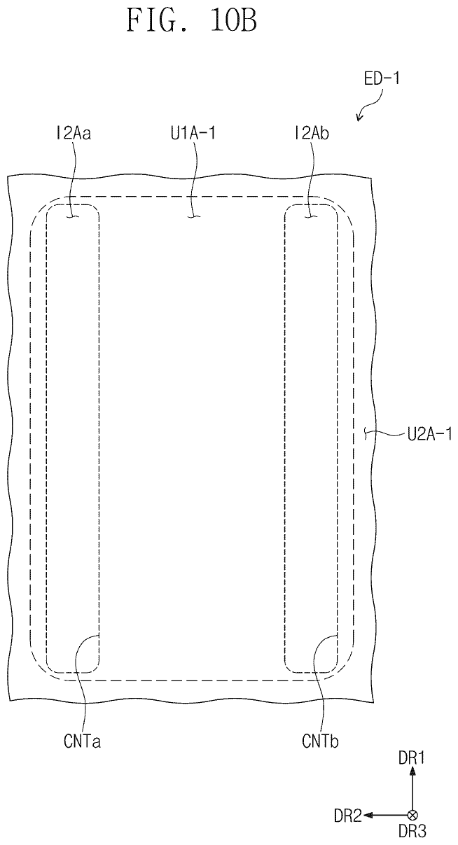

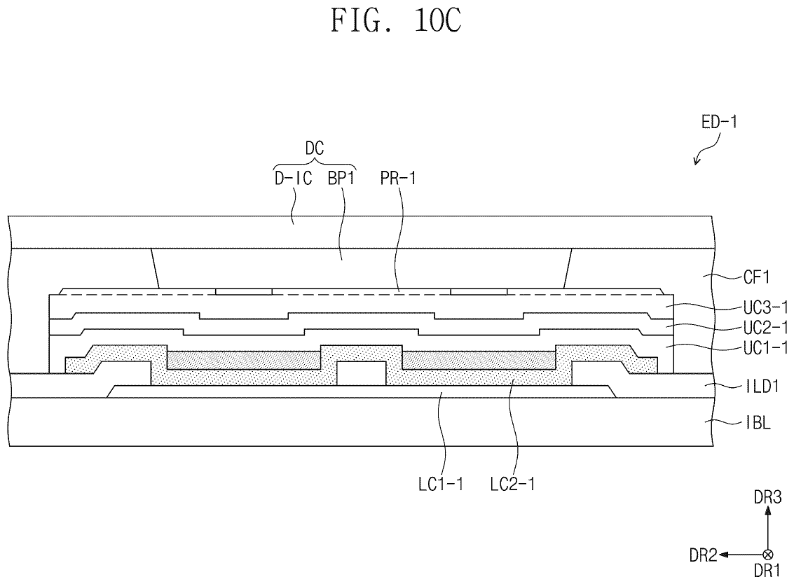

FIG. 10A is an enlarged cross-sectional view of a pad area of an electronic device according to one or more embodiments of the present disclosure. FIG. 10B is an enlarged plan view of a pad area of an electronic device according to one or more embodiments of the present disclosure. FIG. 10C is a cross-sectional view of a bonding structure of an electronic device according to one or more embodiments of the present disclosure.

Hereinafter, in FIGS. 10A to 10C, the same/similar reference numerals denote substantially the same elements in FIGS. 1 to 9E, and thus, more detailed descriptions of substantially the same/similar elements may not be provided.

Referring to FIG. 10A, the electronic device ED-1 may include a base substrate IBL, a first insulating pattern ILD1-1 arranged on the base layer BL, a second insulating patterns ILD2-1 arranged on the first insulating pattern ILD1, and a pad PD-1.

In one or more embodiments, the pad PD-1 may include a first lower conductive pattern LC1-1, a second lower conductive pattern LC2-1, a first upper conductive pattern UC1-1, a second upper conductive pattern UC2-1, and a third upper conductive pattern UC3-1.

A plurality of contact holes CNTa and CNTb may be defined through the first insulating pattern ILD1-1. For example, different from the first insulating pattern ILD1 (refer to FIG. 9A) as described with reference to FIG. 9A, multiple contact holes may be defined through upper surface and rear surface of the first insulating pattern ILD1-1.

The first lower conductive pattern LC1-1 may be exposed through each of the contact holes CNTa and CNTb.

The second lower conductive pattern LC2-1 may include first portions PT1 that are in contact with the first lower conductive pattern LC1-1 exposed through each of the contact holes CNTa and CNTb and second portions PT2-1 and PT2-2 that cover side surface and upper surface of the first insulating pattern ILD1-1. The second portions PT2-1 and PT2-2 may include a second-first portion PT2-1 arranged between the first portions PT1 adjacent to each other and second-second portions PT2-2 except the second-first portion PT2-1.

In one or more embodiments, the second insulating pattern ILD2-1 may be provided in plural. For example, the number of the second insulating patterns ILD2-1 may be substantially the same as the number of the contact holes CNTa and CNTb. The second insulating patterns ILD2-1 may be arranged inside the contact holes CNTa and CNTb, respectively, to prevent a step difference from occurring in the first upper conductive pattern UC1-1 (or reduce a degree to or occurrence of which a step difference occurs in the first upper conductive pattern UC1-1).

The second and third upper conductive patterns UC2-1 and UC3-1 may be sequentially arranged on the first upper conductive patterns UC1-1. The shape of the second upper conductive pattern UC2-1 may be indirectly determined by the shape of the first upper conductive pattern UC1-1, and the shape of the third upper conductive pattern UC3-1 may be indirectly determined by the shape of the second upper conductive pattern UC2-1.

FIG. 10A illustrates the first upper conductive pattern UC1, which has significantly or substantially reduced curvature compared to the first upper conductive pattern UC1′ as described with reference to FIG. 8A as an example.

Referring to FIG. 10B, a second upper area U2A-1 may include a first upper area U1A-1 if (e.g., when) viewed on a plane (e.g., in plan view). The first upper area U1A-1 may include insulating areas I2Aa and I2Ab.

Boundaries of the insulating areas I2Aa and I2Ab may be defined by the contact hole CNTa and CNTb, respectively.

FIG. 10C illustrates a driving chip DC as an electronic component. In one or more embodiments, conductive (e.g., electrically conductive) balls included in the first adhesive layer CF may be arranged between the first bump BP1 and the third upper conductive pattern UC3-1.

The first bump BP1 of the driving chip DC may be in contact with the third upper conductive pattern UC3 due to a bonding pressure after penetrating through the first adhesive layer CF1. Although the step difference is reduced, the third upper conductive pattern UC3 may include a protrusion portion PR-1.

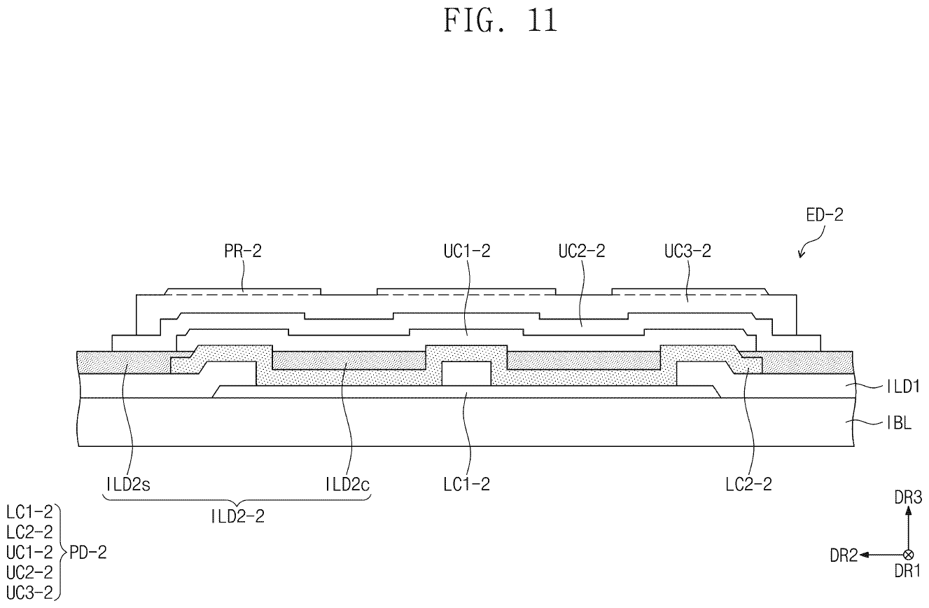

FIG. 11 is an enlarged cross-sectional view of a pad area of an electronic device according to one or more embodiments of the present disclosure.

Hereinafter, in FIG. 11, the same/similar reference numerals denote substantially the same elements in FIGS. 1 to 10C, and thus, more detailed descriptions of substantially the same/similar elements may not be provided.

Referring to FIG. 11, the electronic device ED-2 may include a base substrate IBL, a first insulating pattern ILD1 arranged on the base substrate IBL, a second insulating pattern ILD2-2 arranged on the first insulating pattern ILD1, and a pad PD-2.

The second insulating pattern ILD2-2 may include a second-first insulating pattern ILD2c and a second-second insulating pattern ILD2s.

The second insulating pattern ILD2-2 according to one or more embodiments of the present disclosure may further include the second-second insulating pattern ILD2s compared to the second insulating pattern ILD2-1 (refer to FIG. 10A) as described with reference to FIG. 10A.

The second-second insulating pattern ILD2b may be arranged on the first insulating layer ILD1. The second-second insulating pattern ILD2c may cover a second lower conductive pattern LC2-2.

The second-second insulating pattern ILD2s may be covered by one or more of the first, second, and third upper conductive patterns UC1-2, UC2-2, and UC3-2. FIG. 11 illustrates a structure in which the second-second insulating pattern ILD2c is covered by the first and second upper conductive patterns UC1-2 and UC2-2.

The second-second insulating pattern ILD2s may be exposed by the first, second, and third upper conductive patterns UC1-2, UC2-2, and UC3-2.

The second-second insulating pattern ILD2c may prevent the pad PD-2 from being electrically connected to another pad adjacent to the pad PD-2 (or reduce a degree to or occurrence of which the pad PD-2 is electrically connected to another pad adjacent to the pad PD-2).

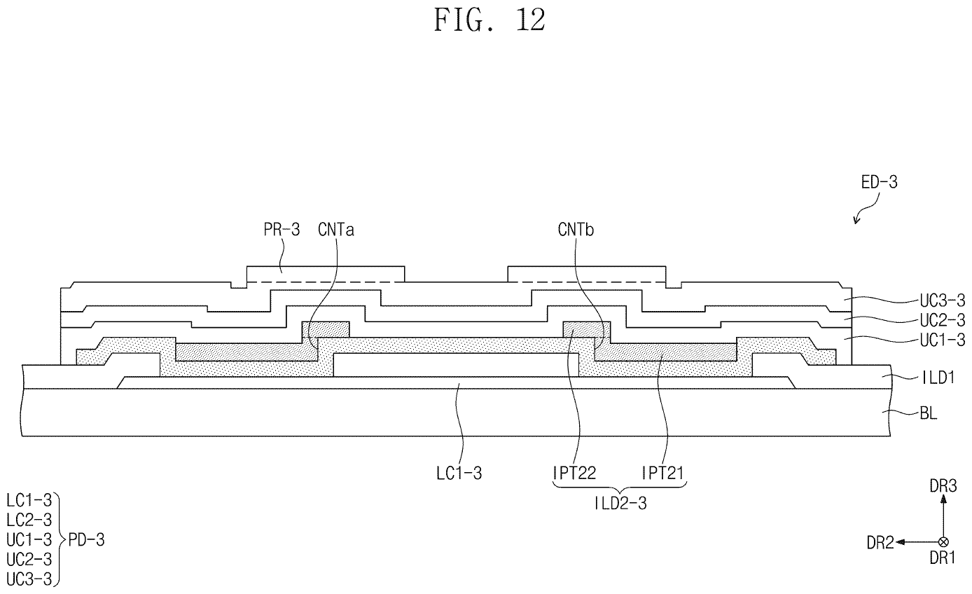

FIG. 12 is an enlarged cross-sectional view of a pad area of an electronic device according to one or more embodiments of the present disclosure.

Hereinafter, in FIG. 12, the same/similar reference numerals denote substantially the same elements in FIGS. 1 to 10C, and thus, more detailed descriptions of substantially the same/similar elements may not be provided.

The electronic device ED-3 may include a base layer substrate IBL, a first insulating pattern ILD1 arranged on the base substrate IBL, a second insulating pattern ILD2-3 arranged on the first insulating pattern ILD1, and a pad PD-3.

The pad PD-3 may include a first lower conductive pattern LC1-3, a second lower conductive pattern LC2-3, a first upper conductive pattern UC1-3, a second upper conductive pattern UC2-3, and a third upper conductive pattern UC3-3.

The second insulating pattern ILD2-3 may be arranged on the first lower conductive pattern LC1-3.

The second insulating pattern ILD2-3 may include a second-first insulating portion IPT21 and a second-second insulating portion IPT22. The second insulating pattern ILD2-3 according to one or more embodiments of the present disclosure may further include the second-second insulating portion IPT22 compared to the second insulating pattern ILD2-1 as described with reference to FIG. 10A.

In FIG. 12, the second-first insulating portion IPT21 and the second-second insulating portion IPT22 are distinguished from each other by a dotted line, however, this is for the convenience of explanation. According to one or more embodiments, the second-first insulating portion IPT21 and the second-second insulating portion IPT22 may be provided in a substantially continuous single unit.

The second-first insulating portion IPT21 may be arranged on the first lower conductive pattern LC1-3. The second-first insulating portions IPT21 may be arranged inside the first contact hole CNTa and the second contact hole CNTb, respectively. The second-first insulating portion IPT21 may be in direct contact with the first lower conductive pattern LC1-3.

The second-second insulating portion IPT22 may be defined by a portion of the second insulating pattern ILD2-3 except the second-first insulating portion IPT21. For example, the second-second insulating portion IPT22 may be portions of the second insulating pattern ILD2-3, which are arranged outside the contact holes CNTa and CNTb.

The second-second insulating portion IPT22 may cover an upper surface of the second lower conductive pattern LC2-3. FIG. 12 illustrates the second-second insulating portion IPT22 extending in an inward direction with respect to the pad PD-3 if (e.g., when) viewed on a plane (e.g., in plan view) as an example, however, embodiments of the present disclosure are not limited thereto. As an example, the second-second insulating portion IPT22 may extend from the second-first insulating portion IPT21 to an outward direction with respect to the pad PD-3.

Referring to FIG. 12, because the protrusion portion PR-3 overlaps the second-second insulating portion IPT22, the protrusion portion PR-3 may be protruded by a thickness of the second-second insulating portion IPT22. For example, the protrusion portion PR-3 according to one or more embodiments of the present disclosure may be protruded in the third direction DR3 by the thickness of the second-second insulating portion IPT22 compared to the protrusion portion PR-1 as described with reference to FIG. 10A. Accordingly, the bonding reliability of the protrusion portion PR-3 according to one or more embodiments of the present disclosure with respect to the first bump BP1 (refer to FIG. 9E) may be improved or enhanced.

A display device, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

Although one or more embodiments of the present disclosure have been described, it should be understood that the present disclosure should not be limited to these embodiments but one or more suitable changes and modifications can be made by one ordinary skilled in the art within the spirit and scope of the present disclosure as hereinafter claimed and equivalents thereof. Therefore, the disclosed subject matter should not be limited to any single embodiment as described herein, and the scope of the present disclosure shall be determined according to the appended claims and equivalents thereof.

What is claimed is:

1. An electronic device comprising:
a base layer;
pixels on the base layer;
signal lines electrically connected to the pixels; and
pads connected to the signal lines, each of the pads comprising:
a first lower conductive pattern on the base layer;
a first insulating pattern through which a contact hole is defined to expose a portion of the first lower conductive pattern, the first insulating pattern covering the first lower conductive pattern;
a second lower conductive pattern comprising:
a first portion covering the first lower conductive pattern exposed through the contact hole; and
a second portion extending from a side surface of the first insulating pattern, which defines the contact hole,
the first portion to cover an upper surface of the first insulating pattern;
a second-first insulating pattern on the first portion;
a first upper conductive pattern on the second-first insulating pattern; and
a second upper conductive pattern on the first upper conductive pattern and being in contact with the first upper conductive pattern.

2. The electronic device as claimed in claim 1, wherein the first upper conductive pattern is not in contact with the first portion and is in contact with the second portion.

3. The electronic device as claimed in claim 1, wherein the contact hole overlaps the first lower conductive pattern in plan view.

4. The electronic device as claimed in claim 1, wherein the second upper conductive pattern has an area greater than an area of the first upper conductive pattern in plan view.

5. The electronic device as claimed in claim 1, wherein each of edges of the second upper conductive pattern is spaced from the first insulating pattern, and the second-first insulating pattern is between the each of the edges of the second upper conductive pattern and the first insulating pattern.

6. The electronic device as claimed in claim 1, wherein the first upper conductive pattern is spaced from the first lower conductive pattern.

7. The electronic device as claimed in claim 1, wherein the second-first insulating pattern is inside the contact hole.

8. The electronic device as claimed in claim 1, wherein a distance between an uppermost portion of the second lower conductive pattern and the first lower conductive pattern is greater than a distance between an upper surface of the second-first insulating pattern and the first lower conductive pattern.

9. The electronic device as claimed in claim 1, further comprising a second-second insulating pattern on the first insulating pattern and spaced from the second-first insulating pattern.

10. The electronic device as claimed in claim 9, wherein the second-second insulating pattern covers the second lower conductive pattern.

11. The electronic device as claimed in claim 1,
wherein each of the first upper conductive pattern and the second upper conductive pattern comprises:
a first layer comprising titanium;
a second layer comprising aluminum; and
a third layer comprising titanium, and
wherein the first layer, the second layer, and the third layer are sequentially stacked in a direction away from the first lower conductive pattern.

12. The electronic device as claimed in claim 1, further comprising a circuit board to apply an electrical signal to the pixels and comprising a bump connecting the second upper conductive pattern and the first upper conductive pattern.

13. The electronic device as claimed in claim 1, further comprising an input sensing layer on the base layer, wherein the input sensing layer comprises:
a first sensing insulating layer, a second sensing insulating layer, and a third sensing insulating layer that are sequentially stacked in a direction away from the first lower conductive pattern;
a first sensing conductive layer between the first sensing insulating layer and the second sensing insulating layer; and
a second sensing conductive layer between the second sensing insulating layer and the third sensing insulating layer.

14. The electronic device as claimed in claim 13, wherein each of the pads further comprises a third upper conductive pattern comprising substantially the same material as one selected from among the first sensing conductive layer and the second sensing conductive layer.

15. An electronic device comprising:
a base layer;
pixels on the base layer;
signal lines electrically connected to the pixels; and
pads connected to the signal lines, each of the pads comprising:
a first lower conductive pattern on the base layer;
a first insulating pattern through which contact holes are defined to expose the first lower conductive pattern, the contact holes being spaced from each other and the first insulating pattern covering the first lower conductive pattern;
a second lower conductive pattern comprising:
first portions covering the first lower conductive pattern exposed through the contact holes; and
second portions extending from a side surface of the first insulating pattern, which defines the contact holes,
the first portions to cover an upper surface of the first insulating pattern;
second-first insulating patterns on the first portions;
a first upper conductive pattern on the second-first insulating patterns and the second lower conductive pattern; and
a second upper conductive pattern on the first upper conductive pattern and being in contact with the first upper conductive pattern.

16. The electronic device as claimed in claim 15, wherein the second-first insulating patterns are in the contact holes adjacent to each other and have a shape extending along one direction in plan view.

17. The electronic device as claimed in claim 15, wherein the first upper conductive pattern is not in contact with the first portions and is in contact with the second portions.

18. The electronic device as claimed in claim 15, further comprising a second-second insulating pattern on the first insulating pattern and spaced from the second-first insulating patterns, wherein the second-second insulating pattern covers the first insulating pattern.

19. The electronic device as claimed in claim 15, further comprising an input sensing layer on the base layer, wherein the input sensing layer comprises:
a first sensing insulating layer, a second sensing insulating layer, and a third sensing insulating layer that are sequentially stacked in a direction away from the first lower conductive pattern;
a first sensing conductive pattern between the first sensing insulating layer and the second sensing insulating layer; and
a second sensing conductive pattern between the second sensing insulating layer and the third sensing insulating layer, and each of the pads further comprises a third upper conductive pattern comprising substantially the same material as one selected from among the first sensing conductive pattern and the second sensing conductive pattern.

20. The electronic device as claimed in claim 19,
wherein each of the second-first insulating patterns comprises:
a second-first insulating portion on the first lower conductive pattern and inside the contact holes; and
a second-second insulating portion outside the contact holes, and
wherein the third upper conductive pattern comprises a protrusion protruded in a direction away from the base layer and overlapping the second-second insulating portion.
